(19) United States
(12) Patent Application Publication
(10) Pub. No.: US 2023/0352512 A1
(43) Pub. Date: Nov. 2, 2023

(54) IMAGING ELEMENT, IMAGING DEVICE, ELECTRONIC EQUIPMENT

(71) Applicant: SONY SEMICONDUCTOR SOLUTIONS CORPORATION, Kanagawa (JP)

(72) Inventors: Hajime YAMAGISHI, Kanagawa (JP); Shota HIDA, Kumamoto (JP)

(73) Assignee: SONY SEMICONDUCTOR SOLUTIONS CORPORATION, Kanagawa (JP)

(21) Appl. No.: 18/002,077

(22) PCT Filed: Jun. 21, 2021
(86) PCT No.: PCT/JP2021/023307

§ 371 Date: Dec. 16, 2022

(30) Foreign Application Priority Data
Jul. 3, 2020 (JP) 2020-115687

(51) Int. Cl. H01L 27/146; G01S 17/89; G01S 17/36

(52) U.S. Cl. CPC H01L 27/14636; H01L 27/14612; G01S 17/89; G01S 17/36

(57) ABSTRACT

The present technique relates to an imaging element, an imaging device, and electronic equipment that enable a wiring capacity and a resistance to be reduced. A semiconductor layer in which pixels including photodiodes, first transfer transistors, and second transfer transistors are arranged in a matrix shape and a wiring layer on the semiconductor layer are included, and a first wiring to which the first transfer transistors of the plurality of pixels arranged in a row direction or a column direction from among the pixels are connected and a second wiring to which the second transfer transistors of the plurality of pixels are connected are included on a side of a second surface of the wiring layer that is opposite to a first surface on which the semiconductor layer is laminated. The present technique can be applied to an imaging element that performs distance measurement, for example.

### TECHNICAL FIELD

The present technique relates to an imaging element, an imaging device, and electronic equipment, and for example, to an imaging element, an imaging device, and electronic equipment in which a semiconductor substrate and a wiring layer are electrically connected.

### BACKGROUND ART

As schemes for measuring a distance, there are a stereo sensor using triangulation based on pattern matching as a basic technique, a Time of Flight (ToF) scheme in which a distance is measured by emitting active light and measuring a time until the reflected light returns, and the like (see PTL 1, for example).

Also, there are a direct ToF scheme and an indirect ToF scheme in the ToF scheme. In the indirect ToF scheme, a distance is indirectly measured by performing photoelectric conversion in a sensor, distributing a charge to two or more electrodes that are present, and obtaining a difference in the charge.

### CITATION LIST

### Patent Literature

[PTL 1]
JP 2016-090268 A

### SUMMARY

### Technical Problem

In the indirect ToF scheme, it is necessary to distribute the charge obtained through photoelectric conversion in the sensor to two or more electrodes at a high speed and to transfer the charge. In a case of 1 M pixels, for example, driving is performed at about several hundreds of MHz. To do this, it is desired that a wiring or the like connected to a gate of a transfer transistor have a low resistance and a low capacity.

The present technique was made in view of such circumstances to enable a semiconductor substrate and a wiring layer to be connected with a low resistance and a low capacity.

### Solution to Problem

An imaging element according to an aspect of the present technique includes: a semiconductor layer in which pixels including photodiodes, first transfer transistors that transfer a charge generated by the photodiodes to a first charge accumulation section, and second transfer transistors that transfer the charge generated by the photodiodes to a second charge accumulation section are arranged in a matrix shape; and a wiring layer that is laminated on the semiconductor layer, a first wiring to which the first transfer transistors of the plurality of pixels arranged in a row direction or a column direction from among the pixels arranged in the matrix shape are connected and a second wiring to which the second transfer transistors of the plurality of pixels are connected being included on a side of a second surface of the wiring layer that is opposite to a first surface on which the semiconductor layer is laminated.

An imaging device according to an aspect of the present technique includes: a semiconductor layer in which pixels including photodiodes, first transfer transistors that transfer a charge generated by the photodiodes to a first charge accumulation section, and second transfer transistors that transfer the charge generated by the photodiodes to a second charge accumulation section are arranged in a matrix shape; and a wiring layer that is laminated on the semiconductor layer, a first wiring to which the first transfer transistors are connected and a second wiring to which the second transfer transistors are connected being included on a side of a second surface of the wiring layer that is opposite to a first surface on which the semiconductor layer is laminated, and a third wiring to which the first wiring of the plurality of pixels arranged in a row direction or a column direction from among the pixels arranged in the matrix shape is connected and a fourth wiring to which the second transfer transistors of the plurality of pixels are connected being included on a side of a surface of a semiconductor substrate, which is laminated on a side of the second surface, and in contact with the second surface.

First electronic equipment according to an aspect of the present technique includes: a distance measurement module that includes an imaging element including a semiconductor layer and a wiring layer, pixels including photodiodes, first transfer transistors that transfer a charge generated by the photodiodes to a first charge accumulation section, and second transfer transistors that transfer the charge generated by the photodiodes to a second charge accumulation section being arranged in a matrix shape in the semiconductor layer, the wiring layer being laminated on the semiconductor layer, a first wiring to which the first transfer transistors of the plurality of pixels arranged in a row direction or a column direction from among the pixels arranged in the matrix shape are connected and a second wiring to which the second transfer transistors of the plurality of pixels are connected being included on a side of a second surface of the wiring layer that is opposite to a first surface on which the semiconductor layer is laminated, a light source that emits irradiation light with a periodically varying brightness, and a light emission control section that controls an irradiation timing of the irradiation light.

Second electronic equipment according to an aspect of the present technique includes: a distance measurement module that includes an imaging device including a semiconductor layer and a wiring layer, pixels including photodiodes, first transfer transistors that transfer a charge generated by the photodiodes to a first charge accumulation section, and second transfer transistors that transfer the charge generated by the photodiodes to a second charge accumulation section being arranged in a matrix shape in the semiconductor layer, the wiring layer being laminated on the semiconductor layer, a first wiring to which the first transfer transistors are connected and a second wiring to which the second transfer transistors are connected being included on a side of a second surface of the wiring layer that is opposite to a first surface on which the semiconductor layer is laminated, and a third wiring to which the first wiring of the plurality of pixels arranged in a row direction or a column direction from among the pixels arranged in the matrix shape is connected and a fourth wiring to which the second transfer transistors of the plurality of pixels are connected being included on a side of a surface of a semiconductor substrate, which is laminated on the side of the second surface, and in contact with the second surface, a light source that emits irradiation light with a periodically varying brightness, and a light emission control section that controls an irradiation timing of the irradiation light.

The imaging element according to the aspect of the present technique includes: the semiconductor layer in which pixels including photodiodes, first transfer transistors that transfer a charge generated by the photodiodes to a first charge accumulation section, and second transfer transistors that transfer the charge generated by the photodiodes to a second charge accumulation section are arranged in a matrix shape; and the wiring layer that is laminated on the semiconductor layer. The first wiring to which the first transfer transistors of the plurality of pixels arranged in the row direction or the column direction from among the pixels arranged in the matrix shape are connected and the second wiring to which the second transfer transistors of the plurality of pixels are connected are included on the side of the second surface that faces the first surface of the wiring layer on which the semiconductor layer is laminated.

The imaging device according to the aspect of the present technique includes: the semiconductor layer in which pixels including photodiodes, first transfer transistors that transfer a charge generated by the photodiodes to a first charge accumulation section, and second transfer transistors that transfer the charge generated by the photodiodes to a second charge accumulation section are arranged in a matrix shape; and the wiring layer that is laminated on the semiconductor layer. The first wiring to which the first transfer transistors are connected and the second wiring to which the second transfer transistors are connected are included on the side of the second surface that faces the first surface of the wiring layer on which the semiconductor layer is laminated. The third wiring to which the first wiring of the plurality of pixels arranged in the row direction or the column direction from among the pixels arranged in the matrix shape is connected and the fourth wiring to which the second transfer transistors of the plurality of pixels are connected are included on the side of the surface of the semiconductor substrate, which is laminated on the side of the second surface, and in contact with the second surface.

The first electronic equipment according to the aspect of the present technique includes a distance measurement module including the imaging element.

The second electronic equipment according to the aspect of the present technique includes a distance module including the imaging device.

Note that the electronic equipment may be an independent apparatus or an internal block constituting a single apparatus.

### BRIEF DESCRIPTION OF DRAWINGS

FIG. 1 is a diagram illustrating a configuration of an embodiment of a distance measurement device to which the present technique is applied.

FIG. 2 is a diagram illustrating a configuration of a light receiving section.

FIG. 3 is a diagram illustrating a circuit configuration example of a pixel.

FIG. 4 is a diagram for explaining distribution of charges in the pixel.

FIG. 5 is a diagram for explaining reading of signals.

FIG. 6 is a diagram illustrating a planar configuration example of the pixel.

FIG. 7 is a diagram illustrating a sectional configuration example of the pixel.

FIG. 8 is a diagram illustrating another sectional configuration example of a pixel.

FIG. 9 is a diagram illustrating splitting examples of a substrate of a light receiving section.

FIG. 10 is a diagram for explaining a splitting example of the substrate of the light receiving section and a bonding surface.

FIG. 11 is a diagram illustrating a sectional configuration example of a light receiving section according to Embodiment 1.

FIG. 12 is a diagram illustrating a configuration example of a wiring according to Embodiment 1-1.

FIG. 13 is a diagram illustrating a configuration example of a wiring according to Embodiment 1-2.

FIG. 14 is a diagram illustrating a configuration example of a wiring according to Embodiment 1-3.

FIG. 15 is a diagram illustrating a configuration example of a wiring according to Embodiment 1-4.

FIG. 16 is a diagram illustrating a configuration example of a wiring according to Embodiment 1-5.

FIG. 17 is a diagram illustrating a configuration example of a wiring according to Embodiment 1-6.

FIG. 18 is a diagram illustrating a configuration example of a wiring according to Embodiment 1-7.

FIG. 19 is a diagram illustrating a sectional configuration example of a light receiving section according to Embodiment 2.

FIG. 20 is a diagram illustrating a configuration example of a wiring according to Embodiment 2-1.

FIG. 21 is a diagram illustrating a configuration example of a wiring according to Embodiment 2-2.

FIG. 22 is a diagram illustrating a configuration example of a wiring according to Embodiment 2-3.

FIG. 23 is a diagram illustrating a configuration example of a wiring according to Embodiment 2-4.

FIG. 24 is a diagram illustrating a configuration example of a wiring according to Embodiment 2-5.

FIG. 25 is a diagram illustrating a configuration example of a wiring according to Embodiment 2-6.

FIG. 26 is a diagram illustrating a configuration example of a wiring according to Embodiment 2-7.

FIG. 27 is a diagram illustrating a sectional configuration example of a light receiving section according to Embodiment 3.

FIG. 28 is a diagram illustrating a configuration example of a wiring according to Embodiment 3-1.

FIG. 29 is a diagram illustrating a configuration example of a wiring according to Embodiment 3-2.

FIG. 30 is a diagram illustrating a configuration example of a wiring according to Embodiment 3-3.

FIG. 31 is a diagram illustrating a configuration example of a wiring according to Embodiment 3-4.

FIG. 32 is a diagram illustrating a configuration example of a wiring according to Embodiment 3-5.

FIG. 33 is a diagram illustrating a configuration example of a distance measurement module.

FIG. 34 is a diagram illustrating a configuration example of electronic equipment.

FIG. 35 is a block diagram showing an example of a schematic configuration of a vehicle control system.

FIG. 36 is an explanatory diagram illustrating an example of installation positions of an outside-vehicle information detecting section and an imaging section.

### DESCRIPTION OF EMBODIMENTS

Hereinafter, modes for carrying out the present technique (hereinafter referred to as “embodiments”) will be described.

The present technique can be applied to a light receiving element included in a distance measurement system that performs distance measurement on the basis of, for example, an indirect TOF scheme, and an imaging device that includes such a light receiving element, or the like.

For example, the distance measurement system can be applied to an in-vehicle system that is mounted in a vehicle and measures a distance to a target outside of the vehicle, a gesture recognition system that measures a distance to a target such as a hand of a user and recognizes a gesture of the user based on a result of the measurement, or the like. In this case, a result of gesture recognition can be used for, for example, an operation or the like of a car navigation system.

### <Configuration Example of Distance Measurement Device>

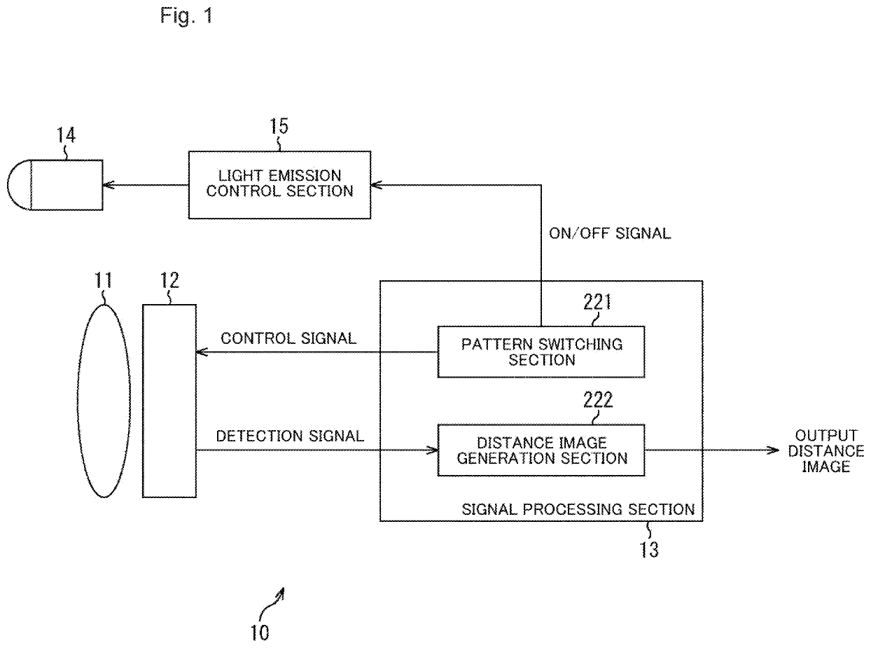

FIG. 1 is a diagram illustrating a configuration example of an embodiment of a distance measurement device to which the present technique is applied.

A distance measurement device 10 includes a lens 11, a light receiving section 12, a signal processing section 13, a light emission section 14, and a light emission control section 15. The signal processing section 13 includes a pattern switching section 21 and a distance image generation section 22. The distance measurement device 10 in FIG. 1 irradiates an object with light, receives the light (irradiation light) reflected by the object (reflected light), and measures the distance to the object.

A light emission system of the distance measurement device 10 includes the light emission section 14 and the light emission control section 15. In the light emission system, the light emission control section 15 causes the light emission section 14 to emit infrared rays (IR) under control of the signal processing section 13. A configuration in which an IR band filter is provided between the lens 11 and the light receiving section 12 and the light emission section 14 emits infrared rays corresponding to a transmission wavelength band of an IR bandpass filter may be employed.

The light emission section 14 may be disposed inside the casing of the distance measurement device 10 and may be disposed outside of the casing of the distance measurement device 10. The light emission control section 15 causes the light emission section 14 to emit light in a predetermined pattern. This pattern is set by the pattern switching section 21 and is switched at a predetermined timing.

The pattern switching section 21 can be provided to switch a light emission pattern so that the light emission pattern does not overlap, for example, a pattern of another distance measurement device 10. The pattern switching section 21 may not be provided.

The signal processing section 13 can function as, for example, a calculating section that calculates a distance from the distance measurement device 10 to an object based on an image signal supplied from the light receiving section 12. When the calculated distance is output as an image, the distance image generation section 22 of the signal processing section 13 generates and outputs a distance image in which a distance to the object is expressed for each pixel.

### <Configuration of Imaging Device>

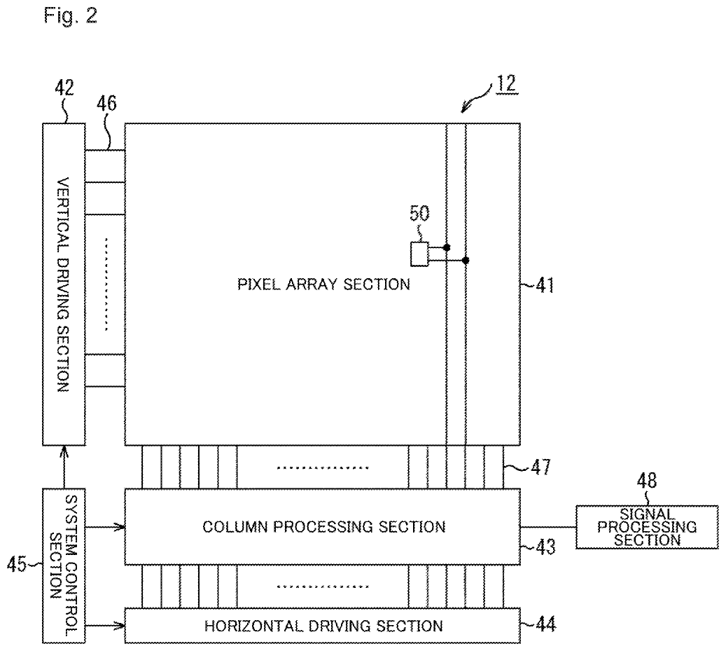

FIG. 2 is a block diagram illustrating a configuration example of the light receiving section 12. The light receiving section 12 can be a complementary metal oxide semiconductor (CMOS) image sensor. In the following description, the light receiving section 12 will also be referred to as an imaging device.

The light receiving section 12 is configured to include a pixel array section 41, a vertical driving section 42, a column processing section 43, a horizontal driving section 44, and a system control section 45. The pixel array section 41, the vertical driving section 42, the column processing section 43, the horizontal driving section 44, and the system control section 45 are provided on a semiconductor substrate (chip), which is not illustrated.

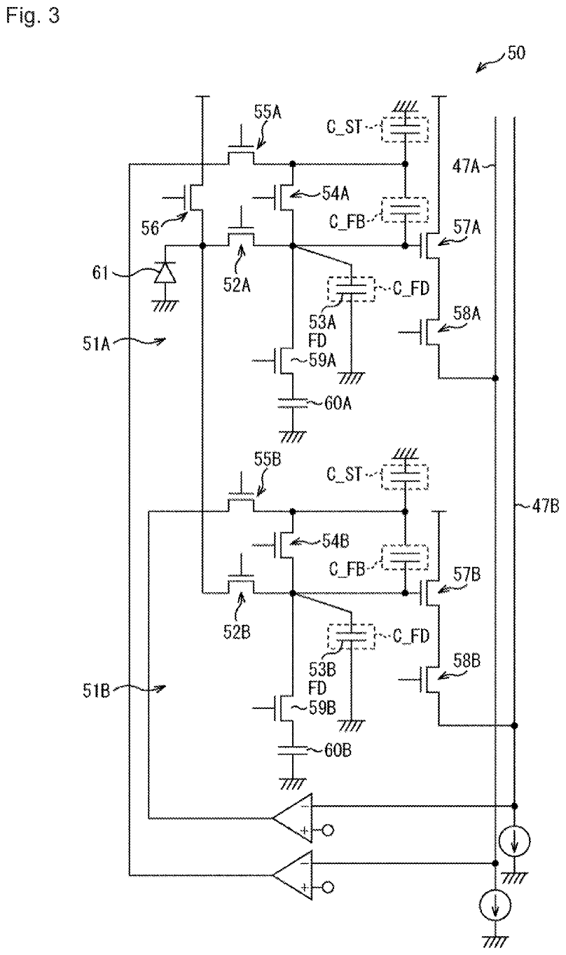

In the pixel array section 41, unit pixels (for example, pixels 50 in FIG. 3) each having a photoelectric conversion element that generates a photocharge of a charge amount according to an amount of incident light and accumulates the photocharge therein are two-dimensionally arranged in a matrix shape.

In the pixel array section 41, a pixel driving line 46 is provided in the horizontal direction in the drawing (an array direction of the pixels in a pixel row) for each row in the pixel array with a matrix form and a vertical signal line 47 is provided in the vertical direction in the drawing (an array direction of the pixels in a pixel column) for each column. One end of the pixel driving line 46 is connected to an output terminal of the vertical driving section 42 corresponding to each row.

The vertical driving section 42 is a pixel driving section that is configured to have a shift register, an address decoder, or the like and drives all the pixels of the pixel array section 41 simultaneously or in units of rows. A pixel signal output from each unit pixel in a pixel row selectively scanned by the vertical driving section 42 is supplied to the column processing section 43 through each vertical signal line 47. The column processing section 43 performs predetermined signal processing on the pixel signal output from each unit pixel of a selected row through the vertical signal line 47 for each pixel column of the pixel array section 41 and temporarily retains the pixel signal after the signal processing.

Specifically, the column processing section 43 performs, at least noise removal processing, for example, correlated double sampling (CDS) processing as signal processing. Fixed pattern noise specific to pixels such as reset noise and variations in threshold value of an amplification transistor is removed through the correlated double sampling performed by the column processing section 43. Note that it is also possible to cause the column processing section 43 to have an analog-to-digital (AD) conversion function, for example, in addition to the noise removal processing and to output a signal level as a digital signal.

The horizontal driving section 44 is configured with a shift register, an address decoder, or the like and selects the unit circuits corresponding to the pixel column of the column processing section 43 in sequence. By this selective scanning performed by the horizontal driving section 44, pixel signals processed by the column processing section 43 are sequentially output to the signal processing section 48.

The system control section 45 includes, for example, a timing generator that generates various timing signals, and performs control of driving of the vertical driving section 42, the column processing section 43, the horizontal driving section 44, and the like on the basis of the various timing signals generated by the timing generator.

In the pixel array section 41, the pixel driving line 46 is wired in the row direction for each pixel row and two vertical signal lines 47 are wired in the column direction for each pixel column in the pixel array of a matrix form. For example, the pixel driving line 46 transfers a driving signal for driving at the time of reading of a signal from the pixel. Note that although one wiring is indicated as the pixel driving line 46 in FIG. 2, the present technique is not limited to one line. One end of the pixel driving line 46 is connected to an output terminal of the vertical driving section 42 corresponding to each row.

### <Structure of Unit Pixel>

Next, a specific structure of the pixels 50 arranged in a matrix shape in the pixel array section 41 will be described. FIG. 3 is a diagram illustrating a circuit configuration example of a pixel 50.

The pixel 50 includes a photodiode 61 (hereinafter, referred to as a PD 61) which is a photoelectric conversion element and is configured such that charges generated in the PD 61 are distributed to a tap 51A and a tap 51B. The charge distributed to the tap 51A out of the charges generated by the PD 61 is read from a vertical signal line 47A and is output as a detection signal SIG1. Also, the charge distributed to the tap 51B is read from the vertical signal line 47B and is output as a detection signal SIG2.

The tap 51A includes a transfer transistor 52A, an FD 53A, a reset transistor 54A, a feedback enable transistor (FBEN) 55A, a discharge transistor (OFG) 56, an amplification transistor 57A, a selection transistor 58A, a conversion efficiency switching transistor (FDG) 59A, and an additional capacitance section 60A.

Similarly, the tap 51B includes a transfer transistor 52B, an FD 53B, a reset transistor 54B, an FBEN 55B, an amplification transistor 57B, a selection transistor 58B, an FDG 59B, and an additional capacitance section 60B.

Note that the reset transistor 54 may be configured to be provided in each of the FD 53A and the FD 53B as illustrated in FIG. 3 or may be configured to be shared by the FD 53A and the FD 53B.

In a case where the configuration in which the reset transistors 54A and 54B are provided in the FD 53A and FD 53B, respectively as illustrated in FIG. 3 is employed, reset timings of the FD 53A and the FD 53B can be individually controlled, and it is thus possible to perform fine control. In a case where the configuration in which the reset transistor 54 is provided commonly for the FD 53A and the FD 53B is employed, the reset timings for the FD 53A and the FD 53B can be the same, and it is thus possible to simplify the control and also to simplify the circuit configuration.

In the following description, the configuration in which the reset transistor 54 is provided in each of the FD 53A and the FD 53B will be described as an example.

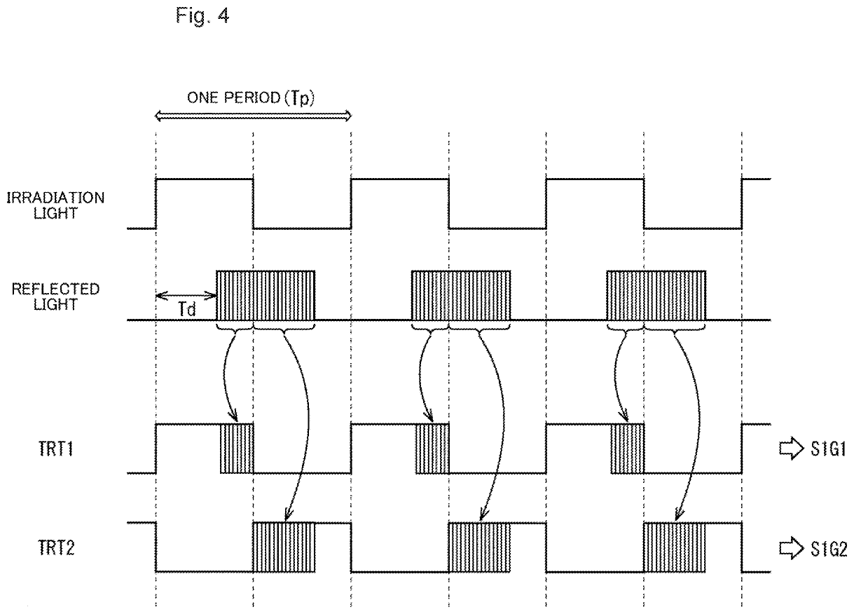

How to distribute the charges in the pixels 50 will be described with reference to FIG. 4. Here, distribution means reading of charges accumulated in the pixels 50 (PDs 61) at different timings and performing the reading for each tap.

As illustrated in FIG. 4, irradiation light modulated so that ON/OFF of the irradiation is repeated at an irradiation time T (one period=Tp) is output from the light emission section 14 and is delayed by a delay time Td in accordance with a distance to an object, and a reflected light is received by the PD 61. A transfer control signal TRT1 controls ON/OFF of the transfer transistor 52A, and a transfer control signal TRT2 controls ON/OFF of the transfer transistor 52B. As illustrated, while the transfer control signal TRT1 has the same phase as the irradiation light, the transfer control signal TRT2 has a phase inverted from that of the transfer control signal TRT1.

Accordingly, the charges generated by the PD 61 receiving the reflected light are transferred to the FD 53A when the transfer transistor 52A is turned on in accordance with the transfer control signal TRT1. The charges are transferred to the FD 53B when the transfer transistor 52B is turned on in accordance with the transfer control signal TRT2. Thus, the charges transferred through the transfer transistor 52A are sequentially accumulated in the FD 53A, and the charges transferred through the transfer transistor 52B are sequentially accumulated in the FD 53B for a predetermined period in which the irradiation with the irradiation light at the irradiation time T is periodically performed. The FD 53 functions as a charge accumulation section that accumulates the charges generated by the PD 61 in this manner.

When the selection transistor 58A is turned on in accordance with a select signal SELm1 after end of the period in which the charges are accumulated, the charges accumulated in the FD 53A are read through the vertical signal line 47A, and the detection signal SIG1 in accordance with the amount of charges is output from the light receiving section 12. Similarly, when the selection transistor 58B is turned on in accordance with a select signal SELm2, the charges accumulated in the FD 53B are read through the vertical signal line 47B, and the detection signal SIG2 in accordance with the amount charges is output from the light receiving section 12.

The charges accumulated in the FD 53A and the charges accumulated in the FD 53B are discharged when the reset transistor 54 is turned on in accordance with the reset signal RST.

In this manner, the pixel 50 can distribute the charges generated by the reflected light received by the PD 61 to the tap 51A and the tap 51B in accordance with the delay time Td and output the detection signal SIG1 and the detection signal SIG2. Also, the delay time Td depends on a time during which the light emitted by the light emission section 14 flies to the object, is reflected by the object, and then flies to the light receiving section 12, that is, the distance to the object. Therefore, the distance measurement device 10 can obtain the distance (depth) to the object in accordance with the delay time Td on the basis of the detection signal SIG1 and the detection signal SIG2.

### <Distance Measurement Method of Indirect TOF Scheme>

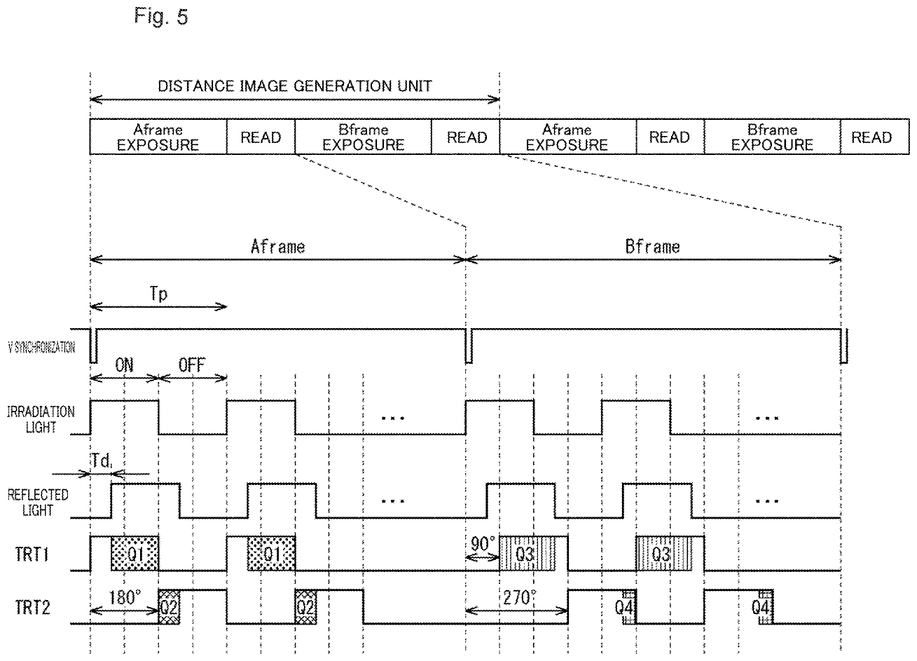

As described above, calculation of a distance in accordance with an indirect TOF scheme in a two-tap scheme in which the charges accumulated in one PD 61 are read using two taps 51 will be described with reference to FIG. 5. A distance measurement method will be additionally described with reference to FIG. 5. In the description with reference to FIG. 5, a two-tap four-phase scheme which is a detection method using two taps and four phases will be described as an example.

One frame period in which a distance image is generated is split into two signal detection periods, namely an A frame and a B frame. One frame period in which a distance image is generated is set to, for example, about 1/30 seconds. Accordingly, a period of the A frame and a period of the B frame are each set to about 1/60 seconds.

Irradiation light modulated so that ON/OFF of irradiation is repeated (one period=Tp) for the irradiation time Tp is output from the light emission section 14 (FIG. 1). The irradiation time Tp can be set to, for example, about 210 ns. The light receiving section 12 receives the reflected light delayed by the delay time Td in accordance with the distance to the object.

In the four-phase scheme, the light receiving section 12 receives the light at four timings, namely the same phase as that of the irradiation light (Phase0), the phase with deviation of 90 degrees (Phase90), the phase with deviation of 180 degrees (Phase180), and the phase with deviation of 270 degrees (Phase270) with any of the tap 51A and the tap 51B. Note that the light reception here is assumed to include processing until the charges generated in the PD 61 are transferred to the FD 53 by turning on the transfer transistor 52.

In FIG. 5, the transfer control signal TRT1 is turned on at the timing of the same phase as that of the irradiation light (Phase0), and light reception is started by the tap 51A in the A frame. Also, the transfer control signal TRT2 is turned on at the timing of the phase with deviation of 180 degrees (Phase180) from the irradiation light, and light reception is started by the tap 51B in the A frame.

Also, the transfer control signal TRT1 is turned on at the timing of the phase with deviation of 90 degrees from the irradiation light (Phase90), and light reception is started by the tap 51A in the B frame. In addition, the transfer control signal TRT2 is turned on at the timing of the phase with deviation of 270 degrees from the irradiation light (Phase270), and light reception is started by the tap 51B in the B frame.

In this case, the taps 51A and 51B receive the light at the timings at which the phase is inverted by 180 degrees. When charges accumulated in the FD 53A of the tap 51A at the timing of Phase® at the irradiation time Tp for a period of the A frame are charges Q1, charges Q1′ in accordance with an accumulation time of the irradiation time Tp within the period of the A frame are accumulated in the FD 53A for the period of the A frame. Also, the charges Q1′ accumulated in the FD 53A are read as a signal corresponding to the detection signal SIG1 from the FD 53A for a reading period. A signal value of the detection signal SIG1 corresponding to the charges Q1′ is assumed to be a signal value I1.

When charges accumulated in the FD 53B of the tap 51B at the timing of Phase180 at the irradiation time Tp are assumed to be charges Q2 for a period of the A frame, charges Q2′ for an accumulation time of the irradiation time Tp within the period of the A frame are accumulated in the FD 53B for the period of the A frame. Also, the charges Q2′ accumulated in the FD 53B are read as a signal corresponding to the detection signal SIG2 from the FD 53B for a reading period. A signal value of the detection signal SIG2 corresponding to the charges Q2′ is assumed to be a signal value 12.

When charges accumulated in the FD 53A of the tap 51A at the timing of Phase90 at the irradiation time Tp are assumed to be charges Q3 for a period of the B frame, charges Q3′ for an accumulation time of the irradiation time Tp within the period of the B frame are accumulated in the FD 53A for the period of the B frame. Also, the charges Q3′ accumulated in the FD 53A are read as a signal corresponding to the detection signal SIG1 from the FD 53A for a reading period. A signal value of the detection signal SIG1 corresponding to the charges Q3′ is assumed to be a signal value 13.

When charges accumulated in the FD 53A of the tap 51B at the timing of Phase270 at the irradiation time Tp are assumed to be charges Q4 for a period of the B frame, charges Q4′ for an accumulation time of the irradiation time Tp within the period of the B frame are accumulated in the FD 53B for the period of the B frame. Also, the charges Q4′ accumulated in the FD 53B are read as a signal corresponding to the detection signal SIG2 from the FD 53B for a reading period. A signal value of the detection signal SIG2 corresponding to the charges Q4′ is assumed to be a signal value 14.

The amount of deviation θ corresponding to the delay time Td can be detected at a distribution ratio of the signal values I1, I2, I3, and I4. In other words, since the delay time Td is obtained on the basis of the amount of phase deviation θ, the distance to the object is obtained in accordance with the delay time Td.

The amount of phase deviation θ is obtained by Equation (1) below, and the distance D to the object is computed by Equation (2) below. In Equation (2), C is a light speed, and Tp represents a pulse width.

$$\begin{matrix}[ Math . 1 ] & \\ θ = arctan ( \frac{{I}_{1} - {I}_{2}}{{I}_{3} - {I}_{4}} ) & ( 1 ) \\ [ Math . 2 ] & \\ D = \frac{θ}{2 π} \times ( \frac{{T}_{P} C}{2} ) & ( 2 )\end{matrix}$$

In this way, it is possible to calculate a distance to a predetermined target. According to such a distance measurement scheme, it is possible to perform distance measurement in which an influence of ambient light is reduced. In the foregoing and following description, only reflected light of emitted pulse light is assumed to be received. However, actually, various kinds of ambient light are simultaneously received in addition to the emitted pulse light. Accordingly, the charges accumulated in the PD 61 depend on the emitted pulse light and the ambient light.

However, in a case where the ambient light can be considered to be regular with respect to a pulse period and is thus regular light, the ambient light are superimposed as offset light equivalent to the signal value I1, the signal value I2, the signal value I3, and the signal value I4. Therefore, the components (offset components) due to the ambient light is canceled in the computation of Equation (1) and does not affect the distance measurement result.

Although the case of the two-tap four-phase scheme TOF-type sensor has been exemplified here as an example, the present technique can also be applied to a TOF-type sensor based on another scheme. For example, the present technique can also be applied to a four-tap four-phase scheme TOF-type sensor.

### <Planar Configuration Example of Pixel>

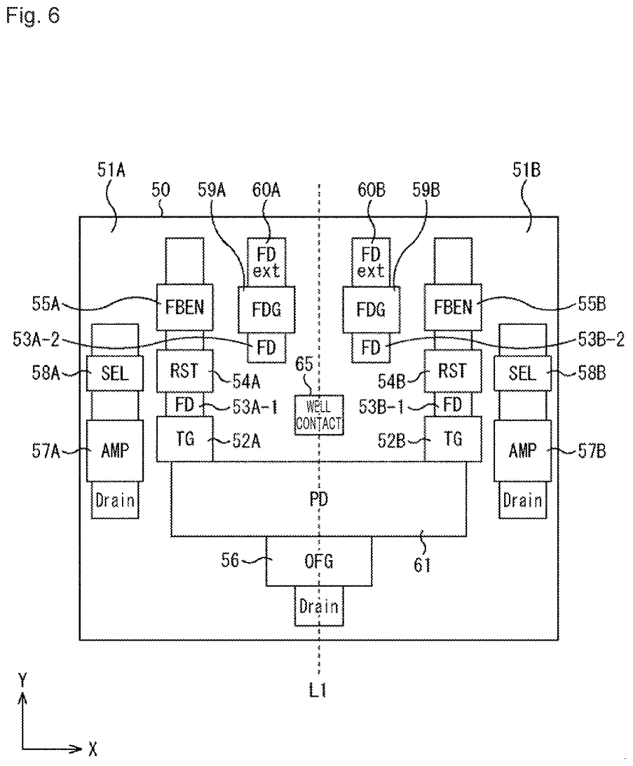

A planar configuration example of the pixel 50 corresponding to the circuit configuration example illustrated in FIG. 3 is illustrated in FIG. 6. As illustrated in FIG. 6, the PD 61 is provided in a region near the center of the rectangular pixel 50. The TG 52A and the TG 52B are provided above (upper side) the PD 61 in the drawing. The TG 52A is a gate portion of the transfer transistor 52A, and the TG 52B is a gate portion of the transfer transistor 52B.

Each of the TG 52A and the TG 52B is provided to be adjacent to one side among the four sides of the PD 61. In the example illustrated in FIG. 6, the TG 52A and the TG 52B are disposed side by side in the X axis direction of the upper side of the PD 61.

An FD 53A-1 is provided above the TG 52A. The FD 53A-1 configures a part of the FD 53A included in the tap 51A. In other words, the FD 53 is configured of two regions in the pixel 50.

The FD 53A included in the tap 51A is configured of the FD 53A-1 and an FD 53A-2. The FD 53A-1 and the FD 53A-2 are formed in different regions. The FD 53A-1 is formed above the TG 52A in the drawing, and the FD 53A-2 is formed at a position separated from the FD 53A-1 at a position on an obliquely upper right side of the FD 53A-1. As will be described later, the FD 53A-1 and the FD 53A-2 are connected with a wiring in the wiring layer and are configured to be able to be handled as one region.

An FDG 59A is formed above the FD 53A-2 in the drawing. The additional capacitance section 60A is formed above the FDG 59A in the drawing. When the FDG 59A is turned on, a state in which the three regions, namely the FD 53A-1, the FD 53A-2, and the additional capacitance section 60A are connected is achieved.

(The gate portion of) the amplification transistor 57A included in the tap 51A is formed on the left side of the TG 52A in the drawing. Also, (the gate portion of) the selection transistor 58A is formed above the TG 52A in the drawing. Further, an FBEN 55A is also provided in the tap 51A, and the FBEN 55A is formed above the reset transistor 54A in the drawing.

In this manner, the FD 53A is distributed and formed in two regions, namely the FD 53A-1 and the FD 53A-2. An RST 54A is connected to the FD 53A-1, and the FBEN 55A is connected to the RST 54A. Also, the FDG 59A is connected to the FD 53A-2. It is possible to connect the FBEN 55A to one side via the RST 54A and to connect the FDG 59A to the other side by arranging the FD 53A in a split manner in the two regions, namely the FD 53A-1 and the FD 53A-2 in this manner.

Each component forming the tap 51B is disposed on the right side of the tap 51A in the drawing. The tap 51B has a configuration similar to that of the tap 51A.

The TG 52B included in the tap 51B is formed on the upper right side of the PD 61 in the drawing. The FD 53B-1 is provided above the TG 52B in the drawing. The FD 53B included in the tap 51B is configured of the FD 53B-1 and the FD 53B-2. The FD 53B-1 is formed above the TG 52B in the drawing, and the FD 53B-2 is formed at a position separated from the FD 53B-1 at a position obliquely upper left side of the FD 53B-1. As will be described later, the FD 53B-1 and the FD 53B-2 are connected with a wiring in the wiring layer and is configured to be able to be handled as one region.

The FDG 59B is formed above the FD 53B-2 in the drawing. The additional capacitance section 60B is formed above the FDG 59B in the drawing. When the FDG 59B is turned on, a state where the three regions, namely the FD 53B-1, the FD 53B-2, and the additional capacitance section 60B are connected is achieved.

(The gate portion of) the amplification transistor 57B included in the tap 51B is formed on the right side of the TG 52B in the drawing. Also, (the gate portion of) the selection transistor 58B is formed above the TG 52B in the drawing. Further, the FBEN 55B is also provided in the tap 51B, and the FBEN 55B is formed above the reset transistor 54B in the drawing.

A well contact 65 is provided above the PD 61. (A gate portion of) a discharge transistor (OFG) 56 is provided below the PD 61. The discharge transistor 56 is an overflow gate for blooming prevention and is configured to be shared by the tap 51A and the tap 51B, and one OFD 56 is thus formed in the pixel 50b as illustrated in FIG. 6.

The layout illustrated in FIG. 6 is an example and is not illustrated to illustrate limitation. Also, although the example illustrated in FIG. 6 illustrates the configuration where the discharge transistor 56 is provided, it is also possible to employ a configuration with no discharge transistor 56.

In the example illustrated in FIG. 6, each part configuring the tap 51A and each part configuring the tap 51B are linearly symmetrically disposed with reference to a center line L1 (the line L1 illustrated by a dotted line in the drawing) of the pixel 50.

In other words, the TG 52A, the FD 53A-1, the FD 53A-2, the reset transistor 54A, the FBEN 55A, the amplification transistor 57A, the selection transistor 58A, the FDG 59A, and the additional capacitance section 60A, which configure the tap 51A, and the TG 52B, the FD 53B-1, the FD 53B-2, the reset transistor 54B, the FBEN 55B, the amplification transistor 57B, the selection transistor 58B, the FDG 59B, and the additional capacitance section 60B, which configure the tap 51B, are linearly symmetrically arranged, respectively.

Although wirings are not illustrated in FIG. 6, the FD 53A-1 and the amplification transistor 57A are connected and configured such that the amount of signal from the FD 53A-1 is supplied to the amplification transistor 57A. The FD 53B-1 and the amplification transistor 57B are connected and are configured such that the amount of signal from the FD 53B-1 is supplied to the amplification transistor 57B.

It is possible to set the length of the wiring between the FD 53A-1 and the amplification transistor 57A to be substantially the same as the length of the wiring between the FD 53B-1 and the amplification transistor 57B by the linear symmetric configuration. Additionally, the other wiring can have the same lengths by the wirings of the bilaterally symmetric targets.

### <Sectional Configuration Example of Pixel>

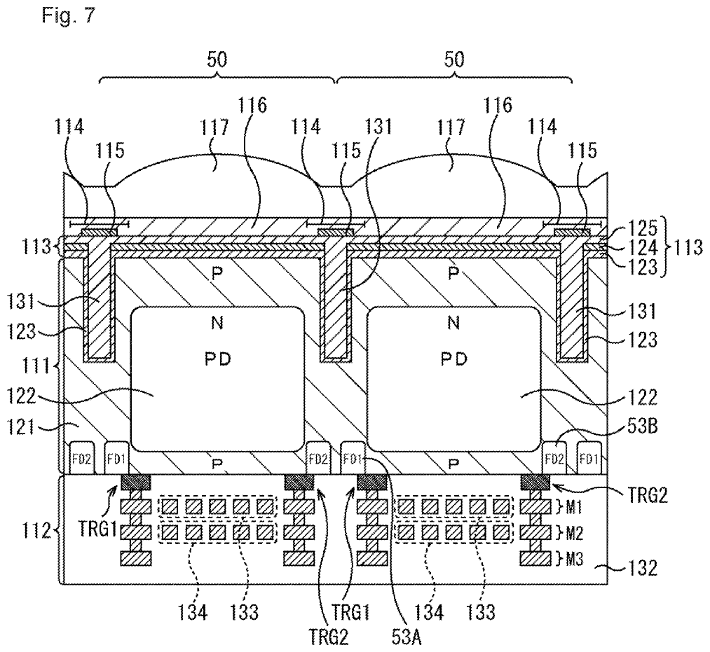

FIG. 7 is a diagram illustrating a sectional configuration example of each pixel 50 including the two taps 51 illustrated in FIGS. 3 and 6.

It is possible to arrange pixels that receive infrared rays, for example, and to arrange pixels used when the distance to the object is measured using signals obtained from the pixels in the pixel array section 41. A sectional configuration of each pixel 50 arranged in the device (distance measurement device) that performs such distance measurement will be additionally described.

FIG. 7 is a sectional view illustrating a configuration example of the pixel 50 arranged in the pixel array section 41. The pixel 50 includes a semiconductor substrate 111 and a multilayered wiring layer 112 formed on the front surface side thereof (the lower side in the drawing).

The semiconductor substrate 111 is configured of silicon (Si), for example, and is formed to have a thickness of 1 to 6 μm, for example. A substrate of a material other than silicon, such as indium gallium arsenide (InGaAs), may be used. An N-type (second conductive type) of semiconductor region 122 is formed in a P-type (first conductive type) semiconductor region 121, for example, in units of pixels, and the photodiode PD is thereby formed in units of pixels in the semiconductor substrate 111. The P-type semiconductor regions 121 provided on both the front and rear surfaces of the semiconductor substrate 111 also serve as hole charge accumulation regions for inhibiting a dark current.

The upper surface of the semiconductor substrate 111 which is located on the upper side in FIG. 7 is the rear surface of the semiconductor substrate 111 and is a light incident surface on which light is incident. An anti-reflection film 113 is formed on the upper surface of the semiconductor substrate 111 on the rear surface side.

The anti-reflection film 113 has a laminated structure in which a fixed charge film and an oxide film are laminated, for example, and it is possible to use a high-dielectric-constant (High-k) insulating film based on an atomic layer deposition (ALD) method, for example. Specifically, it is possible to use a hafnium oxide (HfO2), aluminum oxide (Al2O3), titanium oxide (TiO2), strontium titan oxide (STO), or the like. In the example of FIG. 7, the anti-reflection film 113 is configured by laminating a hafnium oxide film 123, an aluminum oxide film 124, and a silicon oxide film 125.

An inter-pixel light shielding film 115 that prevents incident light from being incident on adjacent pixels is formed on the upper surface of the anti-reflection film 113 at a boundary section 114 of the adjacent pixels 50 (hereinafter, also referred to as a pixel boundary section 114) on the semiconductor substrate 111. The material of the inter-pixel light shielding film 115 may be any material that shields light, and it is possible to use, for example, a metal material such as tungsten (W), aluminum (Al), or copper (Cu).

A flattened film 116 is formed of an insulating film such as silicon oxide (SiO2), silicon nitride (SiN), or silicon oxynitride (SiON) or an organic material such as a resin, for example, on the upper surface of the anti-reflection film 113 and the upper surface of the inter-pixel light shielding film 115.

Also, an on-chip lens 117 is formed for each pixel on the upper surface of the flattened film 116. The on-chip lens 117 is formed of, for example, a resin material such as a styrene resin, an acrylic resin, a styrene-acrylic copolymer resin, or a siloxane resin. Light collected by the on-chip lens 117 is efficiently incident on a photodiode PD.

Also, an inter-pixel separation section 131 that separates adjacent pixels from each other is formed in the depth direction of the semiconductor substrate 111 up to a predetermined depth in the substrate depth direction from the side of the rear surface (the side of the on-chip lens 117) of the semiconductor substrate 111 at the pixel boundary section 114 on the rear surface side of the semiconductor substrate 111. An outer circumferential portion including the bottom surface and the side wall of the inter-pixel separation section 131 is covered with the hafnium oxide film 123 which is a part of the anti-reflection film 113. The inter-pixel separation section 131 prevents incident light from penetrating through the next pixel 50, confines the incident light in its own pixel, and prevents leakage of the incident light from the adjacent pixels 50.

In the example in FIG. 7, although the silicon oxide film 125 as a part of the laminated film that is the anti-reflection film 113 and the inter-pixel separation section 131 are configured of the same material since the silicon oxide film 125 and the inter-pixel separation section 131 are simultaneously formed by embedding the silicon oxide film 125 which is the uppermost layer material of the anti-reflection film 113 in a trench (groove) dug from the rear surface side, the silicon oxide film 125 and the inter-pixel separation section 131 are not necessarily configured of the same material. The material to be embedded in the trench (groove) dug from the rear surface side as the inter-pixel separation section 131 may be a metal material such as tungsten (W), aluminum (Al), titanium (Ti), or titanium nitride (TiN), for example.

On the other hand, two transfer transistor gates TRG1 and TRG2 are formed for one photodiode PD formed for each pixel 50 on the front surface side of the semiconductor substrate 111 on which the multilayered wiring layer 112 is formed. Also, the FD 52A and the FD 52B as charge accumulation sections that temporarily retain charges transferred from the photodiode PD are formed by high-concentration N-type semiconductor regions (N-type diffusion regions) on the front surface side of the semiconductor substrate 111.

The multilayered wiring layer 112 is constituted of a plurality of metal films M and interlayer insulating films 132 therebetween. FIG. 7 illustrates an example in which the multilayered wiring layer 112 is configured of three layers, namely a first metal film M1 to a third metal film M3.

From among the plurality of metal films M in the multilayered wiring layer 112, a wiring 133 is formed in the first metal film M1 which is a predetermined metal film M, and a wiring 134 is formed in the second metal film M2, for example.

As described above, the pixel 50 has a rear surface irradiation type structure in which the semiconductor substrate 111 which is a semiconductor layer is arranged between the on-chip lens 117 and the multilayered wiring layer 112 and incident light is caused to be incident on the photodiode PD from the rear surface side where the on-chip lens 117 is formed.

Also, the pixel 50 includes the two transfer transistor gates TRG1 and TRG2 for the photodiode PD provided for each pixel and is configured to be able to distribute charges (electrons) generated through photoelectric conversion in the photodiode PD to the FD 52A or the FD 52B.

Moreover, the pixel 50 illustrated in FIG. 7 prevents the incident light from penetrating through the next pixel 50, confines the incident light in its pixel, and prevents leakage of the incident light from the adjacent pixels 50 by forming the inter-pixel separation section 131 at the pixel boundary section 114.

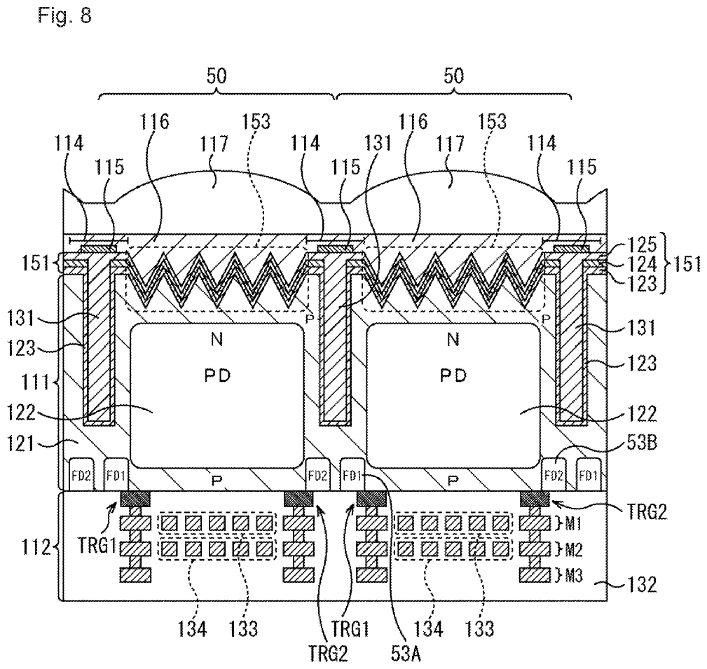

Another sectional configuration of the pixel 50 used for distance measurement will be described with reference to FIG. 8.

In the pixel 50 illustrated in FIG. 8, the same reference signs are applied to parts corresponding to those in the pixel 50 illustrated in FIG. 7, and description of the parts will be appropriately omitted. In the pixel 50 illustrated in FIG. 8, a PD upper region 153 located above the region where the photodiode PD is formed on (the P-type semiconductor region 121 of) the semiconductor substrate 111 has an irregular structure where minute irregularities are formed. Also, the anti-reflection film 151 formed on the upper surface of the irregular structure of the PD upper region 153 on the semiconductor substrate 111 is also formed to have an irregular structure in a manner corresponding thereto. The anti-reflection film 151 is configured through lamination of the hafnium oxide film 123, the aluminum oxide film 124, and the silicon oxide film 125.

It is possible to mitigate a sudden change in refractive index at the substrate interface and to reduce influences of reflected light by causing the PD upper region 153 in the semiconductor region 121 to have the irregular structure in this manner.

Note that in FIG. 8, the inter-pixel separation section 131 formed of DTI formed by being dug from the side of the rear surface (the side of the on-chip lens 117) in the semiconductor region 121 is formed up to a position that is slightly deeper than the inter-pixel separation section 131 in FIG. 7. The depth to which the inter-pixel separation section 131 is formed in the substrate thickness direction can be an arbitrary depth in this manner.

The pixel 50 that can be applied to the following description may be the pixel 50 illustrated in FIG. 7 or the pixel 50 illustrated in FIG. 8.

### <Splitting Examples of Substrate of Light Receiving Section>

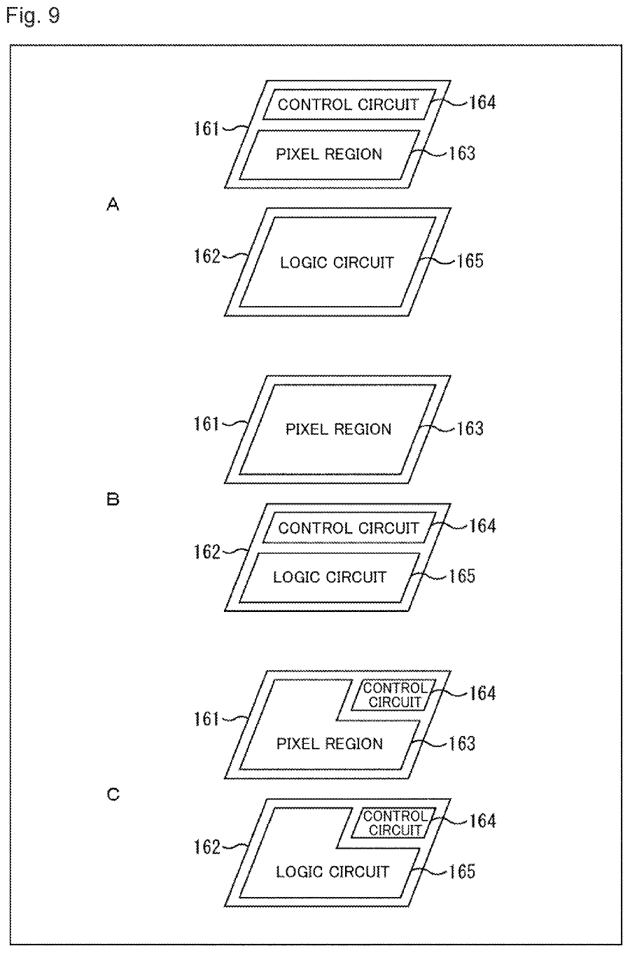

FIG. 9 is a diagram illustrating splitting examples of a substrate in which the light receiving section 12 is configured.

A of FIG. 9 illustrates a first example. The first example is configured of a first semiconductor substrate 161 and a second semiconductor substrate 162. A pixel region 163 and a control circuit 164 are mounted on the first semiconductor substrate 161. A logic circuit 165 including a signal processing circuit is mounted on the second semiconductor substrate 162. Also, an imaging device as one semiconductor chip is configured by the first semiconductor substrate 161 and the second semiconductor substrate 162 being electrically connected to each other.

B of FIG. 9 illustrates a second example. The second example is configured of a first semiconductor substrate 161 and a second semiconductor substrate 162. A pixel region 163 is mounted on the first semiconductor substrate 161. A control circuit 164 and a logic circuit 165 including a signal processing circuit are mounted on the second semiconductor substrate 162. Also, an imaging device as one semiconductor chip is configured by the first semiconductor substrate 161 and the second semiconductor substrate 162 being electrically connected to each other.

C of FIG. 9 illustrates a third example. The third example is configured of a first semiconductor substrate 161 and a second semiconductor substrate 162. A pixel region 163 and a control circuit 164 that controls the pixel region 163 are mounted on the first semiconductor substrate 161. A logic circuit 165 including a signal processing circuit and a control circuit 164 controlling the logic circuit 165 are mounted on the second semiconductor substrate 162. Also, the imaging device as one semiconductor chip is configured by the first semiconductor substrate 161 and the second semiconductor substrate 162 being electrically connected to each other.

### <Laminated Semiconductor Substrate>

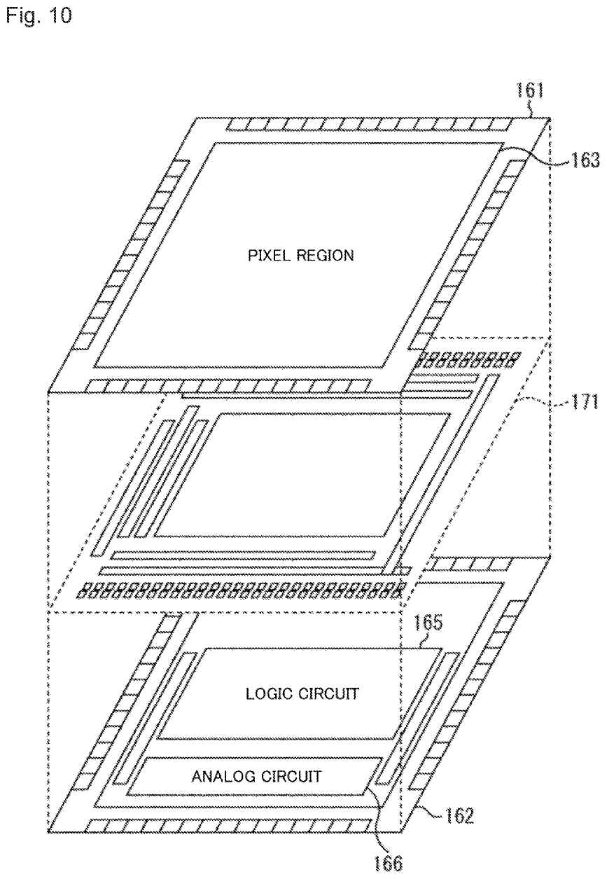

FIG. 10 is a diagram illustrating an example of a relationship between splitting of the substrates in the imaging device and a bonding surface according to the embodiment of the present technique.

The imaging device assumes a rear surface irradiation-type CMOS imaging element. In other words, the first semiconductor substrate 161 including the pixel region 163 which is a light receiving section is disposed at an upper portion of the second semiconductor substrate 162 including a logic circuit 165 and an analog circuit 166. In this manner, a CMOS imaging element with high sensitivity and low noise as compared with the front surface irradiation type is realized.

The bonding surface 171 virtually indicates a bonding surface between the first semiconductor substrate 161 and the second semiconductor substrate 162. At the bonding surface 171, the substrates are attached such that wirings near the bonding surface are bonded directly with each other with mutual multilayered wiring layers facing each other.

### Embodiment 1

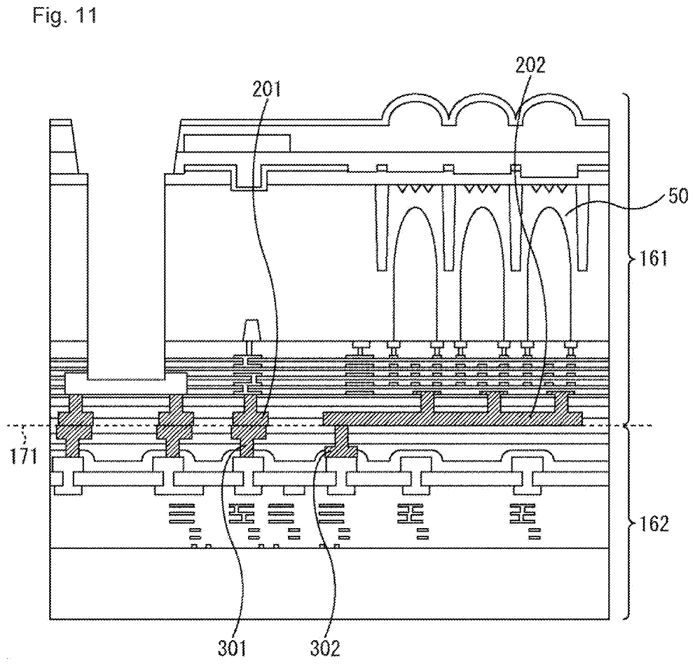

FIG. 11 is a diagram illustrating an example of a schematic sectional view of an imaging device according to Embodiment 1 of the present technique.

In the imaging device, the first semiconductor substrate 161 and the second semiconductor substrate 162 are attached at the bonding surface 171 as described above. In this example, it is possible to use a copper (Cu) wiring as an example of a conductor formed near the bonding surface. The substrates are bonded between wirings 201 and 202 of the first semiconductor substrate 161 and wirings 301 and 302 of the second semiconductor substrate 162.

The wiring 201 and the wiring 301 have a purpose of establishing electrical connection between the first semiconductor substrate 161 and the second semiconductor substrate 162.

In other words, both the wiring 201 and the wiring 301 have connection holes and are formed to establish connection to the inside of the respective substrates.

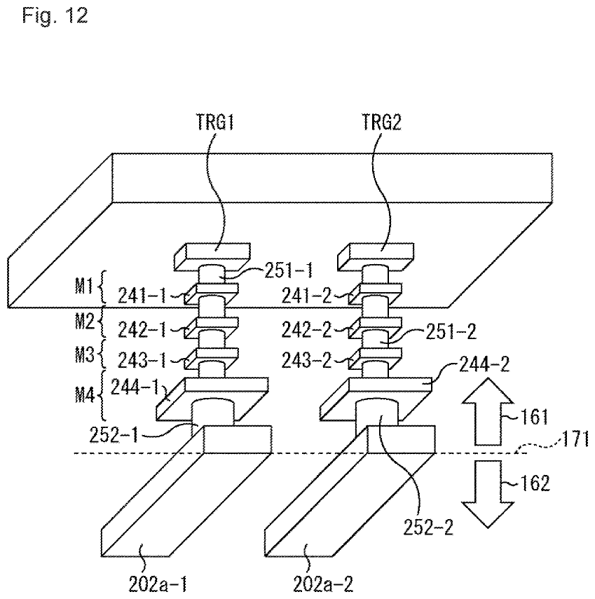

The wiring 202 is formed into a linear shape on the side of the first semiconductor substrate 161 as illustrated in FIG. 11. Although the wiring 202 has a linear shape in the sectional view illustrated in FIG. 11, the wiring 202 is formed into a rectangular parallelepiped shape having a predetermined width, a predetermined thickness, and a predetermined length as will be described later with reference to FIG. 12 and the like.

Each pixel 50 having the sectional configuration illustrated in FIG. 8 is formed on the first semiconductor substrate 161. The pixel 50 illustrated in FIG. 8 includes the transfer transistor gate TRG1 and the transfer transistor gate TRG2. The transfer transistor gates TRG1 or the transfer transistor gate TRG2 of the plurality of pixels 50 are connected to the wiring 202 formed into the linear shape.

The wiring 202 is connected to the wiring 302 formed in the second semiconductor substrate 162. In this manner, the wiring 202 is connected to the plurality of pixels 50 inside the first semiconductor substrate 161 and is connected to the one wiring 302 of the second semiconductor substrate 162.

Note that although description will be continued here on the assumption that the wiring 202 is connected to the one wiring 302, the one wiring 301 may be formed by being dispersed into a plurality of pieces, or a dummy wiring may be formed as will be described later.

Hereinafter, description of the wiring 202 formed into a linear shape on the side of the first semiconductor substrate 161 will be additionally given.

### Embodiment 1-1

FIG. 12 is a diagram illustrating a configuration of a wiring 202 according to Embodiment 1-1 (the wiring 202 in Embodiment 1-1 will be described as a wiring 202a). Note that the drawings in the following embodiments are drawings in which the wiring 202 and a contact and the like connected to the wiring 202 are illustrated while the other parts are omitted.

The first semiconductor substrate 161 is a substrate which is also called as a CMOS image sensor (CIS) substrate or the like. A plurality of pixels 50 are formed on the first semiconductor substrate 161 as illustrated in FIG. 11. When one pixel 50 is focused, the one pixel 50 includes the transfer transistor gate TRG1 and the transfer transistor gate TRG2 as described above with reference to FIGS. 7 and 8.

The transfer transistor gate TRG1 is connected to a wiring 241-1, a wiring 242-1, a wiring 243-1, and a wiring 244-1 formed in a first metal film M1 to a fourth metal film M4, respectively, of the multilayered wiring layer 112 via a via 251-1 formed in the vertical direction.

The wiring 244-1 is connected to the wiring 202a-1 via a connection terminal 252-1. Note that the connection terminal 252-1 can be formed by a via.

Similarly, the transfer transistor gate TRG2 is connected to a wiring 241-2, a wiring 242-2, a wiring 243-2, and a wiring 244-2 formed in the first metal film M1 to the fourth metal film M4, respectively, of the multilayered wiring layer 112 via a via 251-2 formed in the vertical direction. The wiring 244-2 is connected to the wiring 202a-2 via a connection terminal 252-2.

The transfer transistor gate TRG1 is connected to the wiring 202a-1, and the transfer transistor gate TRG2 is connected to the wiring 202a-2. The wiring 202a-1 and the wiring 202a-2 are connected to the wiring 302 formed in the second semiconductor substrate 162.

Since the wiring related to the transfer transistor gate TRG1 and the wiring related to the transfer transistor gate TRG2 have similar configurations, the wiring related to the transfer transistor gate TRG1 will be described as an example in the following description. Also, in a case where it is not necessary to distinguish the wiring 241-1 and the wiring 241-2 from each other, for example, they will be simply referred to as a wiring 241 in the following description. Other parts will be described in a similar manner.

The wiring 202a is formed into a rectangular parallelepiped shape. The shape is an example and may have a side surface (section) having a square shape, a polygonal shape, or the like. Also, the transfer transistor gates TRG1 of the plurality of pixels 50 arranged in the row direction or the column direction from among the plurality of pixels 50 arranged in the pixel array section 41 are connected to the wiring 202a-1.

Additionally, the transfer transistor gates TRG2 arranged in the row direction or the column direction from among the plurality of pixels 50 arranged in the pixel array section 41 are connected to the wiring 202a-2.

The direction in which the transfer transistor gates TRG1 of the plurality of pixels 50 are aligned is the lengthwise direction of the wiring 202a-1. The length of the wiring 202a-1 in the lengthwise direction can be a length that is substantially equivalent to the total length of the sides of the plurality of pixels 50 arranged in the lengthwise direction. Also, in a case where a direction that perpendicularly intersects the lengthwise direction is assumed to be a widthwise direction, the length (assumed to be a width) of the wiring 202a-1 in the widthwise direction can be equal to or less than the width that is equivalent to the diameter (one side) of the connection terminal 252.

Also, the wiring 202a can be formed of a conductor and can be wiring for distributing power in the bonding surface direction.

The thickness of the wiring 202a-1 can be a predetermined thickness. In a case where a resistance value may be raised by miniaturizing the wiring 202a-1 or the like, it is also possible to employ design with the thickness of the wiring 202a-1 increased to lower the resistance value.

Although the wiring 202a is formed into a rectangular parallelepiped shape as described above, the wiring 302 formed in the second semiconductor substrate 162 and connected to the wiring 202a is formed into a shape such as a prism or a cylinder and is connected to a part of the wiring 202a. With such formation, it is possible to prevent the capacity generated between the wiring 202a and the wiring 302 from increasing even if deviation occurs in bonding adjustment in the process of bonding the wiring 202a to the wiring 302. It is thus possible to curb influences of an increase in capacity due to a decrease in space between adjacent wirings caused by the deviation in bonding adjustment and of variations in capacity.

The same applies to the wiring 202a-2.

According to the present technique, it is possible to curb influences of an increase in capacity caused between adjacent wirings and of variations in capacity even if positioning accuracy is not high when the first semiconductor substrate 161 and the second semiconductor substrate 162 are laminated (connected). Also, it is possible to employ a structure that curbs an increase in resistance value and to realize a low resistance. It is also possible to obtain such an effect even when the pixels are miniaturized.

### Embodiment 1-2

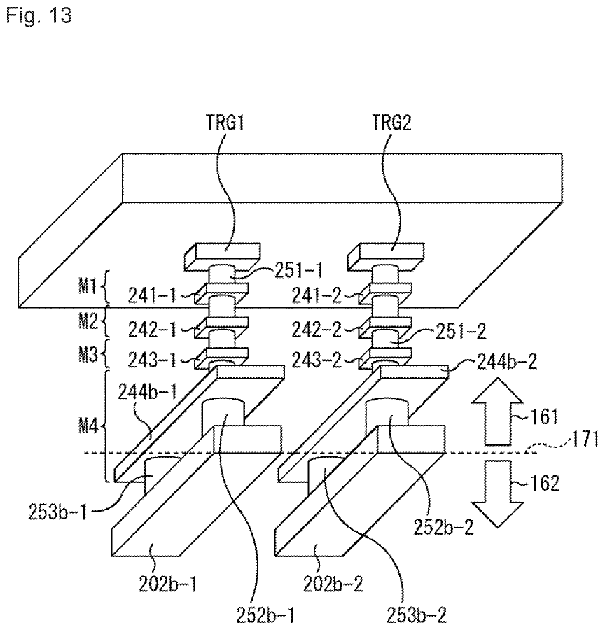

FIG. 13 is a diagram illustrating a configuration of a wiring 202b according to Embodiment 1-2. In a case where the wiring 202b according to Embodiment 1-2 is compared with the wiring 202a according to Embodiment 1-1, the wiring 202b is different from the wiring 202a in that the wiring 202b is configured such that a backing via 253b is added to the wiring 202a and the wiring 244b is configured into a rectangular parallelepiped shape for connection to the backing via 253b, and the other points are similar therebetween.

The backing via 253b-1 is added and connected to the wiring 202b-1 illustrated in FIG. 13. In other words, a connection terminal 252b-1 and a backing via 253b-1 are connected to the wiring 202b-1.

The backing via 253b-1 can be formed of the same material as that of the connection terminal 252b-1, for example, Cu (copper). Also, the backing via 253b-1 can be formed to have a shape and a size that are similar to those of the connection terminal 252b-1.

A wiring 244b-1 arranged in the fourth metal film M4 is formed to have such a size with which connection to both the connection terminal 252b-1 and the backing via 253b-1 can be established. Also, the wiring 244b-1 is formed to have a length in the lengthwise direction that is equivalent to the length of one side of the pixel 50. Although the wiring 244b-1 is provided for each pixel 50, it is possible to employ a configuration in which the wirings 244b-1 provided for the pixels 50 are connected to each other to be formed into one continuous straight line shape.

Alternatively, the length of the wiring 244b-1 in the lengthwise direction may be formed to be shorter than one side of the pixel 50, and the wirings 244b-1 provided for the pixels 50 may be provided for the respective pixels 50 without being connected to each other. The thickness of the wiring 244b-1 is determined depending on the thickness of the fourth metal film M4.

In this manner, it is possible to lower the resistance value by employing the configuration in which the backing via 253b is added and the wiring 244b is formed to have such a size with which connection to the backing via 253b can be established. According to Embodiment 1-2, it is possible to lower the resistance value as compared with Embodiment 1-1.

The wiring 202b illustrated in FIG. 13 is connected to the connection terminal 252b and the backing via 253b. In other words, the wiring 202b illustrated in FIG. 13 is connected to the wiring 244b via the two vias. The wiring 202b may be configured to be connected to the wiring 244b via two or more vias per pixel 50. In other words, it is possible to provide a plurality of backing vias 253 per pixel 50.

According to Embodiment 1-2, it is also possible to curb influences of an increase in capacity caused between adjacent wirings and of variations in capacity similarly to Embodiment 1-1. It is also possible to obtain such an effect even when the pixels are miniaturized.

### Embodiment 1-3

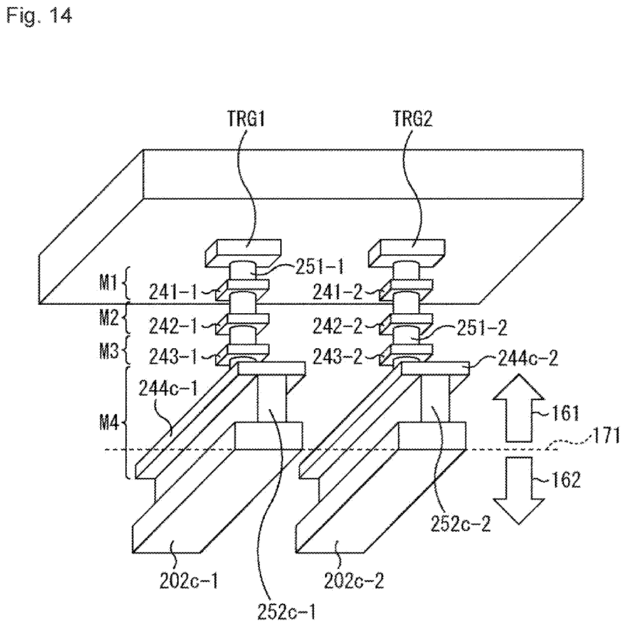

FIG. 14 is a diagram illustrating a configuration of a wiring 202c according to Embodiment 1-3.

The wiring 202c according to Embodiment 1-3 includes a connection terminal 252c formed into a rectangular parallelepiped shape instead of the backing via 253b in Embodiment 1-2. The connection terminal 252c-1 is provided between a wiring 202c-1 and a wiring 244c-1 and is formed as a connection terminal for connecting the wiring 202c-1 to the wiring 244c-1.

Also, the connection terminal 252c is formed to have a length in the lengthwise direction that is equivalent to the length of one side of the pixel 50. Although the connection terminal 252c is provided for each pixel 50, the connection terminals 252c provided for the pixels 50 may be connected and formed in one continuous straight line shape.

Alternatively, the connection terminal 252c may be formed to have a length in the lengthwise direction that is shorter than one side of the pixel 50, and the connection terminals 252c provided for the pixels 50 may be individually provided without being connected to each other.

The wiring 244c-1 arranged in the fourth metal film M4 is formed to have such a size with which connection to the connection terminal 252c-1 formed into a rectangular parallelepiped shape can be established. The wiring 244b-1 is formed to have a size in the lengthwise direction that is equivalent to that of the connection terminal 252c. Also, the thickness of the wiring 244c-1 is determined depending on the thickness of the fourth metal film M4.

It is possible to lower the resistance value by configuring the connection terminal 252c into a rectangular parallelepiped shape in this manner. According to Embodiment 1-3, it is possible to lower the resistance value as compared with Embodiment 1-1. Additionally, according to Embodiment 1-3, it is also possible to curb influences of an increase in capacity caused between adjacent wirings and of variations in capacity similarly to Embodiment 1-1. It is also possible to obtain such an effect even when the pixels are miniaturized.

### Embodiment 1-4

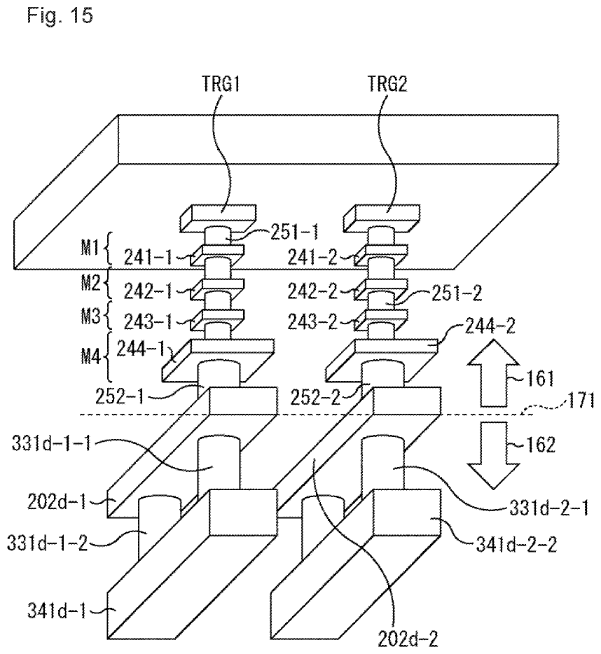

FIG. 15 is a diagram illustrating a configuration of a wiring 202d according to Embodiment 1-4.

In the wiring 202d according to Embodiment 1-4, a part corresponding to the backing via 253b in Embodiment 1-2 is formed as a backing via 331d on the side of the second semiconductor substrate 162. Parts related to the wiring 202d and the like of the first semiconductor substrate 161 in Embodiment 1-4 are similar to those related to the wiring 202a and the like in Embodiment 1-1.

The wiring 202d-1 illustrated in FIG. 15 is connected to a backing via 331d-1-1 and a backing via 331d-1-2 formed in the second semiconductor substrate 162. Each of the backing via 331d-1-1 and the backing via 331d-1-2 is provided in order to obtain a structure for lowering the resistance value of the wiring 202d-1, which is the same reason for providing the backing via 253b-1 illustrated in FIG. 13.

Also, the second semiconductor substrate 162 is provided with a wiring 341d-1 for connecting the two backing vias 331d-1-1 and 331d-1-2 to the wiring formed on the side of the second semiconductor substrate 162. The wiring 341d-1 has the same role as that of the wiring 244b-1 illustrated in FIG. 13, and the backing via 331d-1-1 and the backing via 331d-1-2 are connected thereto.

The wiring 341d is formed to have a length in the lengthwise direction that is equivalent to the length of one side of the pixel 50. Although the wiring 341d is provided for each pixel 50, the wirings 341d provided for the pixels 50 may be connected and formed into one continuous straight line shape.

Alternatively, the wiring 341d may be formed to have a length in the lengthwise direction that is shorter than the length of one side of the pixel 50, and the wirings 341d provided for the pixels 50 may be individually provided without being connected to each other.

It is possible to lower the resistance value of the entire wiring connected to the wiring 202d by forming the backing via 331d at a corresponding part of the second semiconductor substrate 162 connected to the wiring 202d provided in the first semiconductor substrate 161 and forming the wiring 341d connected to the backing via 331d on the side of the second semiconductor substrate 162.

Additionally, according to Embodiment 1-4, it is also possible to curb influences of an increase in capacity caused between adjacent wirings and of variations in capacity similarly to Embodiment 1-1. It is also possible to obtain such an effect even when the pixels are miniaturized.

### Embodiment 1-5

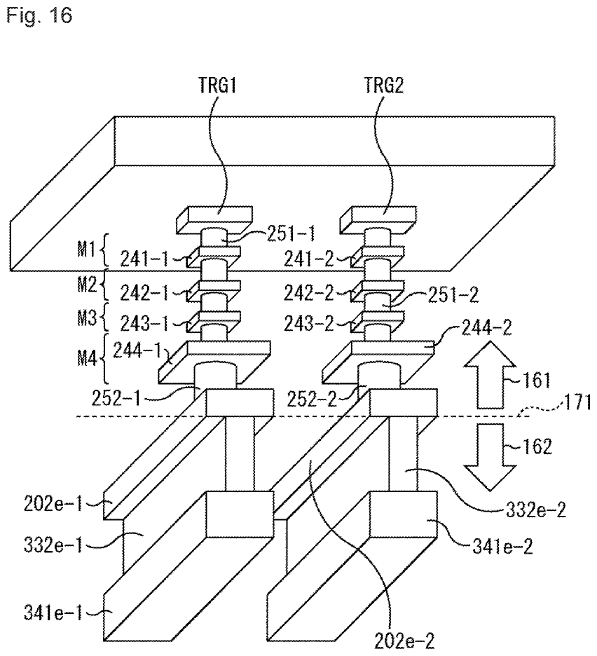

FIG. 16 is a diagram illustrating a configuration of a wiring 202e according to Embodiment 1-5.

A wiring 202d according to Embodiment 1-5 includes a backing trench 332e formed into a straight line shape instead of the backing via 331d in Embodiment 1-4.

The backing trench 332e-1 is provided in the second semiconductor substrate 162. Also, the backing trench 332 is provided between a wiring 202e-1 provided in the first semiconductor substrate 161 and a wiring 341e-1 provided in the second semiconductor substrate 162 and is formed as a connection terminal that connects the wiring 202e-1 to the wiring 341e-1.

Additionally, the backing trench 332e may be formed to have a length in a lengthwise direction that is equivalent to the length of one side of the pixel 50, and the backing trenches 332e provided for the pixels 50 may be connected and formed in a continuous straight line shape.

Alternatively, the wiring 341d may be formed to have a length in the lengthwise direction that is shorter than one side of the pixel 50, and the wirings 341d provided for the pixels 50 may be individually provided without being connected to each other.

Also, although the example in which the backing trench 332e has a length in the widthwise direction that is shorter than the lengths of the wiring 202e-1 and the wiring 341e-1 has been illustrated in the example illustrated in FIG. 16, the length of the backing trench 332e may be longer to the equivalent length.

The wiring 341e-1 is formed to have a length in the lengthwise direction that is equivalent to the length of the backing trench 332e.

It is possible to lower the resistance value by configuring the backing trench 332e in a rectangular parallelepiped shape in this manner. According to Embodiment 1-5, it is possible to lower the resistance value as compared with Embodiment 1-1.

Additionally, according to Embodiment 1-5, it is also possible to curb influences of an increase in capacity caused between adjacent wirings and of variations in capacity similarly to Embodiment 1-1. It is also possible to obtain such an effect even when the pixels are miniaturized.

### Embodiment 1-6

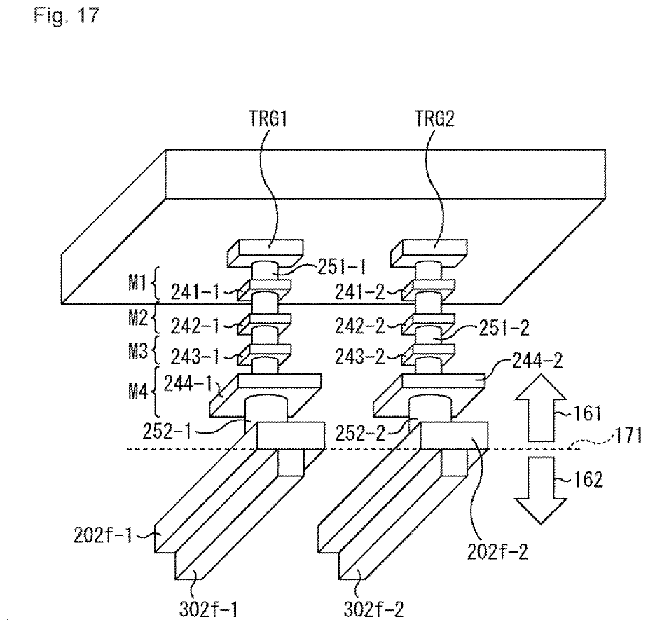

FIG. 17 is a diagram illustrating a configuration of a wiring 202f according to Embodiment 1-6.

The wiring 202f according to Embodiment 1-6 corresponds to a case where the backing trench 332e according to Embodiment 1-5 is used as a wiring 302f. The backing trench 332e may be provided as the wiring 302f and may be caused to function as a wiring (formed to be able to transmit and receive signals) or may be provided as a dummy wiring. The case where the wiring 302f is caused to function as a wiring will be additionally described in Embodiment 3, which will be described later.

The dummy wiring is a wiring which is not an essential configuration for transmission, reception, and the like of signals, and does not affect operations of the imaging element even if the dummy wiring is not provided. The wiring 302f illustrated in FIG. 17 is formed as a dummy wiring.

The wiring 302f is formed into a rectangular parallelepiped shape. Although the example in which the wiring 302f is formed to have a width that is shorter than that of the wiring 202f has been described in the example illustrated in FIG. 17, the width of the wiring 302f may be equivalent to that of the wiring 202f. Alternatively, the wiring 302f may be formed to have a line width that is different from the line width of the wiring 202f and may be formed to have a line width difference of equal to or greater than 20%, for example.

Since the wiring 302f is a dummy wiring, the wiring 302f may be formed to have a length in the lengthwise direction that is equivalent to the length of one side of the pixel 50, and the wirings 302f provided for the pixels 50 may be formed into one continuous straight line shape, similarly to the backing trench 332e (FIG. 16) described above, for example.

Alternatively, the wiring 302f may be formed to have a length in the lengthwise direction that is shorter than one side of the pixel 50, and the wirings 302f provided for the pixels 50 may be individually provided without being connected to each other.

It is possible to lower the resistance value of the wiring 202f connected to the wiring 302f and to improve connection strength by forming the wiring 302f into a rectangular parallelepiped shape. Additionally, according to Embodiment 1-6, it is also possible to curb influences of an increase in capacity caused between adjacent wirings and of variations in capacity similarly to Embodiment 1-1. It is also possible to obtain such an effect even when the pixels are miniaturized.

### Embodiment 1-7

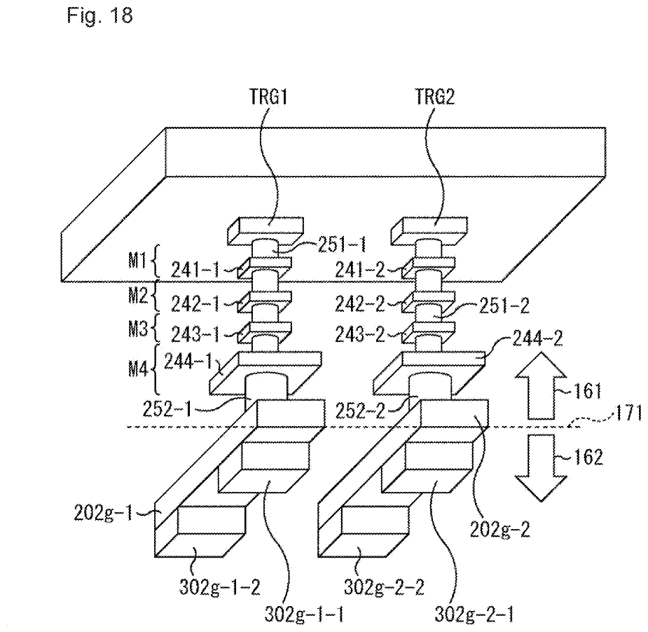

FIG. 18 is a diagram illustrating a configuration of a wiring 202g according to Embodiment 1-7.

The wiring 202g according to Embodiment 1-7 corresponds to a case where the backing via 331d (FIG. 15) according to Embodiment 1-4 is used as a wiring 302g.

A wiring 302g-1-1 and a wiring 302g-1-2 are connected to the wiring 202g-1. The wiring 302g-1-1 and the wiring 302g-1-2 are provided as dummy wirings to lower the resistance value and improve connection strength.

As illustrated in FIG. 18, the wiring 302g may be formed as a dummy wiring and may be formed into a dot shape. It is possible to lower the resistance value of the wiring 202g connected to the wiring 302g and to improve connection strength by forming the wiring 302g into a dot shape.

Additionally, according to Embodiment 1-7, it is also possible to curb influences of an increase in capacity caused between adjacent wirings and variations in capacity similarly to Embodiment 1-1. It is also possible to obtain such an effect even when the pixels are miniaturized.

### Embodiment 2

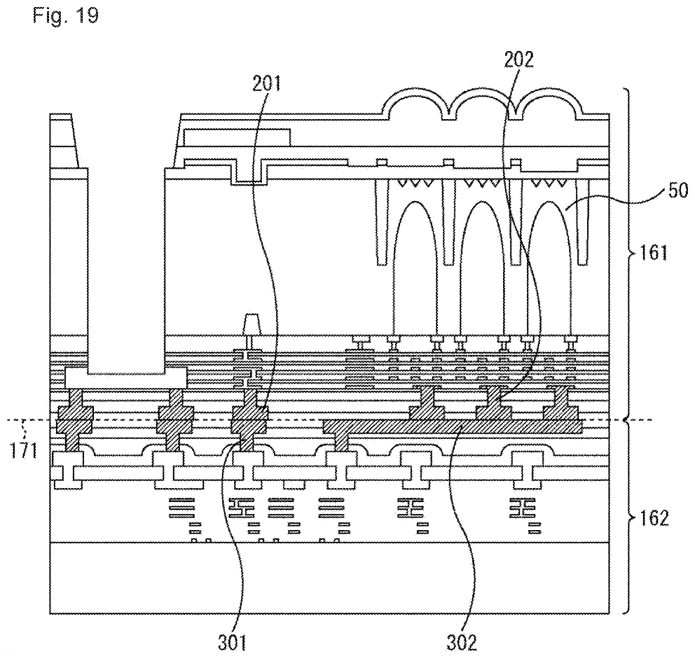

FIG. 19 is a diagram illustrating an example of a schematic sectional view of an imaging device according to Embodiment 2 of the present technique. The imaging device according to Embodiment 2 also basically has the same configuration as that of the imaging device (FIG. 11) according to Embodiment 1.

In the imaging device, the first semiconductor substrate 161 and the second semiconductor substrate 162 are attached at the bonding surface 171 as described above. In this example, it is possible to use a copper (Cu) wiring as an example of a conductor formed near the bonding surface. The substrates are bonded between wirings 201 and 202 of the first semiconductor substrate 161 and wirings 301 and 302 of the second semiconductor substrate 162.

The wiring 201 and the wiring 301 have a purpose of establishing electrical connection between the first semiconductor substrate 161 and the second semiconductor substrate 162. In other words, both the wiring 201 and the wiring 301 have connection holes and are formed to establish connection to the inside of the respective substrates.

The wiring 202 is provided for each pixel 50 in a similar shape to that of the wiring 201 on the side of the first semiconductor substrate 161 as illustrated in FIG. 19. Specifically, the wiring 202 is provided for each of the transfer transistor gate TRG1 and the transfer transistor gate TRG2 of the pixel 50.

Each wiring 202 is connected to the wiring 302 formed in the second semiconductor substrate 162.

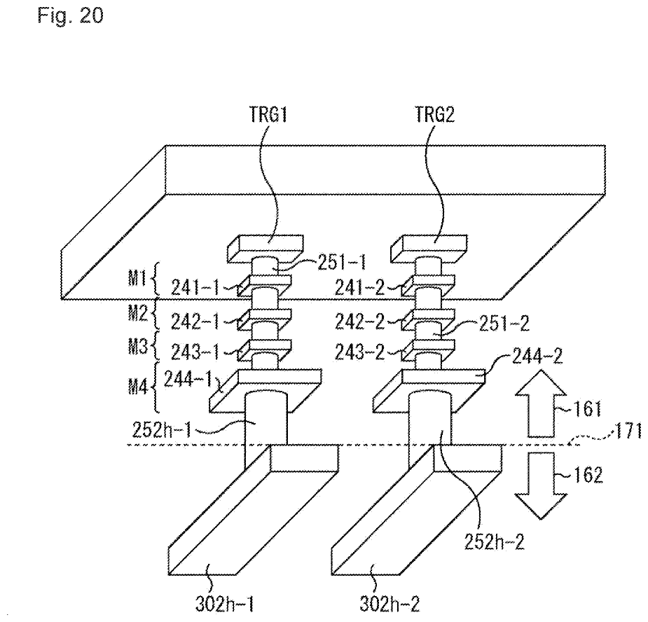

The wiring 302 is formed into a linear shape as illustrated in FIG. 19. Although the wiring 302 has a linear shape in the sectional view illustrated in FIG. 19, the wiring 202 is formed into a rectangular parallelepiped shape having a predetermined width, a predetermined thickness, and a predetermined length as will be described later with reference to FIG. 20 and the like.

The wiring 302 formed into a linear shape is connected to the transfer transistor gates TRG1 or the transfer transistor gates TRG2 of the plurality of pixels 50 via the wiring 202. In this manner, the wiring 302 is connected to each of the plurality of pixels 50 inside the first semiconductor substrate 161.

Hereinafter, the wiring 302 formed into a linear shape on the side of the second semiconductor substrate 162 will be additionally described.

### Embodiment 2-1

FIG. 20 is a diagram illustrating a configuration of a wiring 302h according to Embodiment 2-1. Note that the drawings in the following embodiments are drawings in which the wiring 302 and a contact and the like connected to the wiring 302 are illustrated while the other parts are omitted.

The first semiconductor substrate 162 is a substrate which is also called a CIS substrate or the like. Also, the second semiconductor substrate 162 is a substrate which is also called a logic circuit substrate or the like. A plurality of pixels 50 are formed on the first semiconductor substrate 161 as illustrated in FIG. 19. When one pixel 50 is focused, the one pixel 50 includes the transfer transistor gate TRG1 and the transfer transistor gate TRG2 as described above with reference to FIGS. 7 and 8.

The transfer transistor gate TRG1 is connected to a wiring 241-1, a wiring 242-1, a wiring 243-1, and a wiring 244-1 formed in a first metal film M1 to a fourth metal film M4, respectively, of the multilayered wiring layer 112 via a via 251-1 formed in the vertical direction.

The wiring 244-1 is connected to a wiring 302h-1 via a connection terminal 252h-1. Note that the connection terminal 252h-1 can be formed by a via. Also, the connection terminal 252h-1 corresponds to the wiring 202 (FIG. 19).

The transfer transistor gate TRG1 is connected to the wiring 302h-1, and the transfer transistor gate TRG2 is connected to the wiring 302h-2. The wiring 302h is a wiring formed in the second semiconductor substrate 162.

The wiring 302h is formed into a rectangular parallelepiped shape. The shape is an example and may be a shape with a side surface (section) having a square shape, a polygonal shape, or the like. Also, (a connection terminal 252h connected to) the transfer transistor gates TRG1 of the plurality of pixels 50 are connected to the wiring 302h-1.

The direction in which the transfer transistor gates TRG1 of the plurality of pixels 50 are aligned is a lengthwise direction of the wiring 302h-1. The length of the wiring 302h-1 in the lengthwise direction can be the length that is substantially equivalent to the total of the lengths of the sides of the plurality of pixels 50 arranged in the lengthwise direction. Also, in a case where the direction that perpendicularly intersects the lengthwise direction is assumed to be a widthwise direction, the length (assumed to be a width) of the wiring 302h-1 in the widthwise direction can be equal to or less than the width that is equivalent to the diameter (one side) of the connection terminal 252h.

The thickness of the wiring 302h can be a predetermined thickness. In a case where the resistance value may be raised by miniaturizing the wiring 302h, and the like, it is possible to employ a design for lowering the resistance value by increasing the thickness of the wiring 302h.

Although the wiring 302h is formed into a rectangular parallelepiped shape as described above, the connection terminal 252h formed in the first semiconductor substrate 161 and connected to the wiring 302h is formed into a shape such as a prism or a cylinder and is connected to a part of the wiring 302a. It is possible to prevent the capacity generated between the wiring 302h and the wiring 202h from increasing even if deviation occurs in bonding adjustment in the process of bonding the wiring 302h to the connection terminal 252h (wiring 202h) by employing such formation. It is thus possible to curb influences of an increase in capacity due to a decrease in space between adjacent wirings caused by the deviation in bonding adjustment and of variations in capacity.

The same applies to the wiring 302h-2.

According to the present technique, it is possible to curb influences of an increase in capacity caused between adjacent wirings and of variations in capacity even if accuracy of positioning when the second semiconductor substrate 162 and the first semiconductor substrate 161 are laminated (connected) is not high. Also, it is possible to employ a structure that curbs an increase in resistance value and to realize a low resistance. It is also possible to obtain such an effect even when the pixels are miniaturized.

### Embodiment 2-2

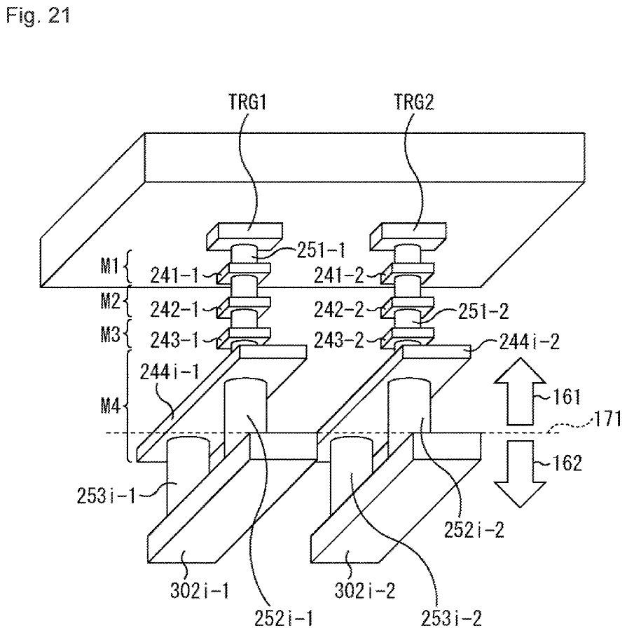

FIG. 21 is a diagram illustrating a configuration of a wiring 302i according to Embodiment 2-2. In comparison between the wiring 302i according to Embodiment 2-2 and the wiring 302h according to Embodiment 2-1, the wiring 302i is different in that it has a configuration in which the backing via 253i is added to the wiring 302h and the wiring 244i is also configured in a rectangular parallelepiped shape in order to establish connection to the backing via 253i, and the other points are similar.

The backing via 253i-1 is added and connected to the wiring 302i-1 illustrated in FIG. 21. In other words, a connection terminal 252i-1 and a backing via 253i-1 are connected to the wiring 302i-1. The connection terminal 252i-1 and the backing via 253i-1 are formed in the first semiconductor substrate 161.

The backing via 253i-1 can be formed of the same material as that of the connection terminal 252i-1, for example, Cu (copper). Also, the backing via 253i-1 can be formed to have a shape and a size that are similar to those of the connection terminal 252i-1.

A wiring 244i-1 arranged in the fourth metal film M4 is formed to have such a size with which connection to both the connection terminal 252i-1 and the backing via 253i-1 can be established. Also, the wiring 244i-1 is formed to have a length in the lengthwise direction that is equivalent to the length of one side of the pixel 50. Although the wiring 244i-1 is provided for each pixel 50, it is possible to employ a configuration in which the wirings 244i-1 provided for the pixels 50 are connected to each other to be formed into one continuous straight line shape.

Alternatively, the length of the wiring 244i-1 in the lengthwise direction may be formed to be shorter than one side of the pixel 50, and the wirings 244i-1 provided for the pixels 50 may be provided for the respective pixels 50 without being connected to each other. The thickness of the wiring 244i-1 is determined depending on the thickness of the fourth metal film M4.

In this manner, it is possible to lower the resistance value by employing the configuration in which the backing via 253i is added and the wiring 244i is formed to have such a size with which connection to the backing via 253i can be established. According to Embodiment 2-2, it is possible to lower the resistance value as compared with Embodiment 2-1. Additionally, according to Embodiment 2-2, it is possible to curb influences of an increase in capacity caused between adjacent wirings and of variations in capacity similarly to Embodiment 2-1. It is also possible to obtain such an effect even when the pixels are miniaturized.

### Embodiment 2-3

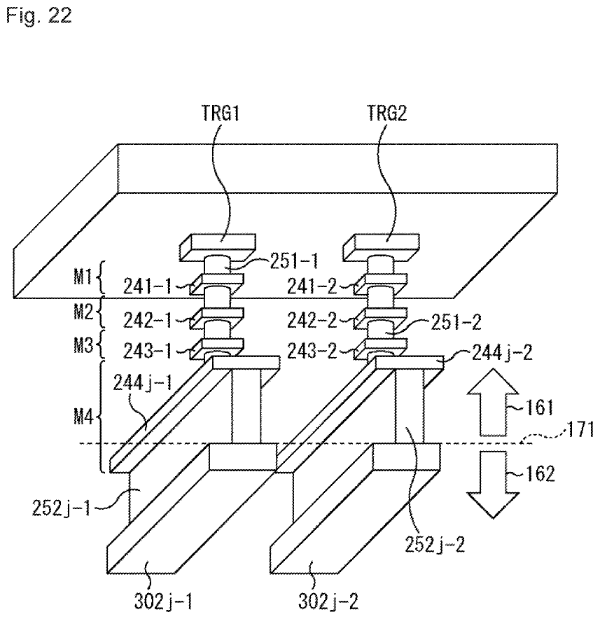

FIG. 22 is a diagram illustrating a configuration of a wiring 302j according to Embodiment 2-3.

The wiring 302j according to Embodiment 2-3 includes a connection terminal 252j formed into a rectangular parallelepiped shape instead of the backing via 253i according to Embodiment 2-2. The connection terminal 252j-1 is provided in the first semiconductor substrate 161 and is formed as a connection terminal that is provided between a wiring 302j-1 and a wiring 244j-1 and connects the wiring 302j-1 to the wiring 244j-1.

Also, the connection terminal 252j is formed to have a length in the lengthwise direction that is equivalent to the length of one side of the pixel 50. Although the connection terminal 252j is provided for each pixel 50, the connection terminals 252j provided for the pixels 50 may be connected and formed in one continuous straight line shape.

Alternatively, the connection terminal 252j may be formed to have a length in the lengthwise direction that is shorter than one side of the pixel 50, and the connection terminals 252j provided for the pixels 50 may be individually provided without being connected to each other.

The wiring 244j-1 arranged in the fourth metal film M4 is formed to have such a size with which connection to the connection terminal 252j-1 formed into a rectangular parallelepiped shape can be established. The wiring 244i-1 is formed to have a size in the lengthwise direction that is equivalent to the size of the connection terminal 252j-1. Also, the thickness of the wiring 244j-1 is determined depending on the thickness of the fourth metal film M4.

It is possible to lower the resistance value by configuring the connection terminal 252j into a rectangular parallelepiped shape in this manner. According to Embodiment 2-3, it is possible to lower the resistance value as compared with Embodiment 2-1. Additionally, according to Embodiment 2-3, it is also possible to curb influences of an increase in capacity caused between adjacent wirings and of variations in capacity similarly to Embodiment 2-1. It is also possible to obtain such an effect even when the pixels are miniaturized.

### Embodiment 2-4

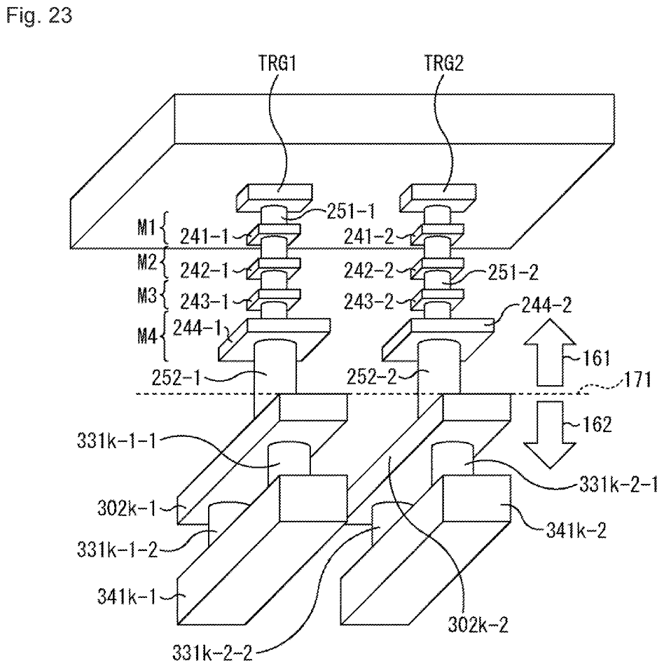

FIG. 23 is a diagram illustrating a configuration of a wiring 302k according to Embodiment 2-4.

In the wiring 302k according to Embodiment 2-4, the part corresponding to the backing via 253i according to Embodiment 2-2 is formed as a backing via 331k on the side of the second semiconductor substrate 162. The parts related to the wirings on the side of the first semiconductor substrate 161 according to Embodiment 2-4 are similar to the part related to the wirings according to Embodiment 2-1.

The wiring 302k-1 illustrated in FIG. 23 is connected to a backing via 331k-1-1 and a backing via 331k-1-2 formed in the second semiconductor substrate 162. Each of the backing via 331k-1-1 and the backing via 331k-1-2 is provided in order to obtain a structure for lowering the resistance value of the wiring 302k-1, which is the same reason for providing the backing via 253i-1 illustrated in FIG. 21.

Also, the second semiconductor substrate 162 is provided with a wiring 341k-1 for connecting a backing via 331k-1-1 and a backing via 331k-1-2 to a wiring formed in the second semiconductor substrate 162. The wiring 341k-1 is connected to the backing via 331k-1-1 and the backing via 331k-1-2.

The wiring 341k is formed to have a length in a lengthwise direction that is equivalent to or shorter than the length of the wiring 302k.

It is possible to lower the resistance value of the entire wiring connected to the wiring 302k by forming the backing via 331k connected to the wiring 302k provided in the second semiconductor substrate 162 and forming the wiring 341k connected to the backing via 331k in the second semiconductor substrate 162 in this manner.

Additionally, according to Embodiment 2-4, it is also possible to curb influences of an increase in capacity caused between adjacent wirings and of variations in capacity similarly to Embodiment 2-1. It is also possible to obtain such an effect even when the pixels are miniaturized.

### Embodiment 2-5

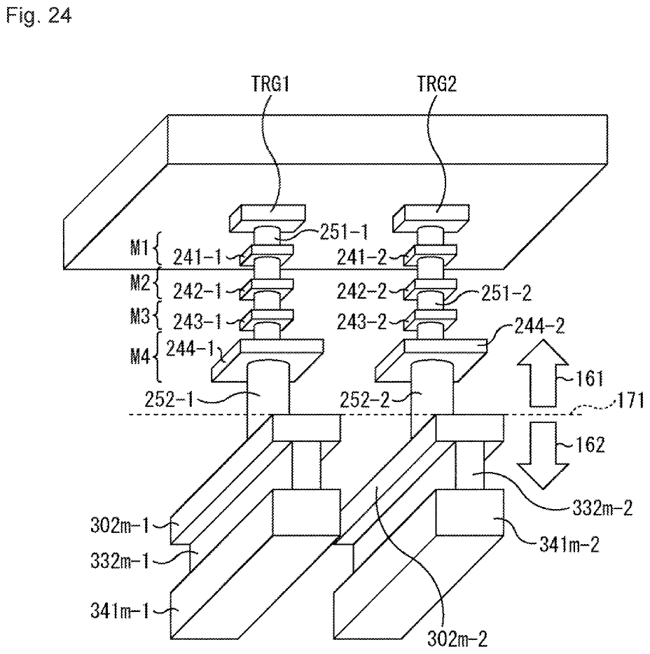

FIG. 24 is a diagram illustrating a configuration of a wiring 302m according to Embodiment 2-5.

A wiring 302k according to Embodiment 2-5 includes a backing trench 332m formed into a straight line shape instead of the backing via 331k in Embodiment 2-4.

The backing trench 332m-1 is provided in the second semiconductor substrate 162. Also, the backing trench 332 is provided between a wiring 302m-1 and a wiring 341m-1 provided in the second semiconductor substrate 162 and is formed as a connection terminal for connecting the wiring 302m-1 to the wiring 341m-1.

The backing trench 332m is formed to have a length in the lengthwise direction that is equivalent to or shorter than the length of the wiring 302m.

Also, although the example in which the backing trench 332m is formed to have a length (width) in the widthwise direction that is shorter than the lengths of the wiring 302m-1 and the wiring 341m-1 has been described in the example illustrated in FIG. 24, the length of the backing trench 332m in the widthwise direction may be increased up to the length that is equivalent thereto.

The wiring 341m-1 is formed to have a length in the lengthwise direction that is equivalent to the length of the backing trench 332m-1.

It is possible to lower the resistance value by configuring the backing trench 332m in a rectangular parallelepiped shape in this manner. According to Embodiment 2-5, it is possible to lower the resistance value as compared with Embodiment 2-1.

Additionally, according to Embodiment 2-5, it is possible to curb influences of an increase in capacity caused between adjacent wirings and of variations in capacity similarly to Embodiment 2-1. It is also possible to obtain such an effect even when the pixels are miniaturized.

### Embodiment 2-6

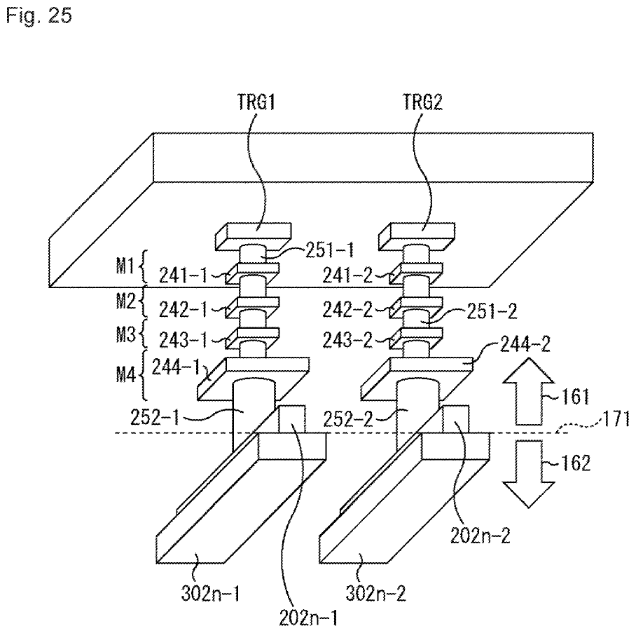

FIG. 25 is a diagram illustrating a configuration of a wiring 302n according to Embodiment 2-6.

The wiring 302n according to Embodiment 2-6 is connected to a wiring 202n provided as a dummy wiring. The dummy wiring 202n may function as wiring (formed to be able to transmit and receive signals) or may be provided as a dummy wiring. The case where the wiring 202n is caused to function as a wiring will be additionally described in Embodiment 3, which will be described later.

The wiring 202n is formed into a rectangular parallelepiped shape. Although the example in which the wiring 202n is formed to have a width that is shorter than that of the wiring 302n has been described in the example illustrated in FIG. 25, the width of the wiring 202n may be equivalent to that of the wiring 302n.

The wiring 202n is a dummy wiring and is formed to be equivalent to or shorter than the wiring 302m similarly to the aforementioned backing trench 332m (FIG. 24), for example.

It is possible to lower the resistance value of the wiring 302n connected to the wiring 202n and to improve connection strength by forming the wiring 202n into a rectangular parallelepiped shape. Additionally, according to Embodiment 2-6, it is also possible to curb influences of an increase in capacity caused between adjacent wirings and of variations in capacity similarly to Embodiment 2-1. It is also possible to obtain such an effect even when the pixels are miniaturized.

### Embodiment 2-7

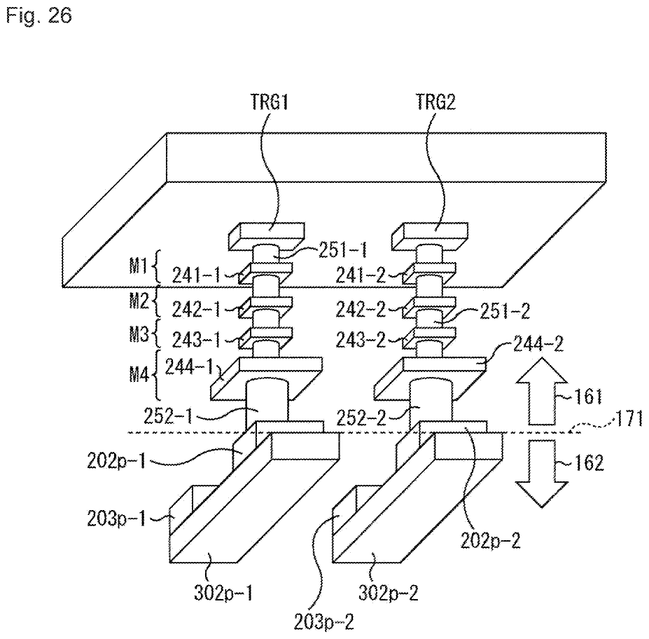

FIG. 26 is a diagram illustrating a configuration of a wiring 302p according to Embodiment 2-7.

A wiring 202p-1 and a wiring 203p-1 are connected to the wiring 302p according to Embodiment 2-7. The wiring 202p-1 is connected to the transfer transistor gate TRG1 and functions as a terminal for supplying a signal from the transfer transistor gate TRG1 to the circuit in the second semiconductor substrate 162 via the wiring 302p-1.

The wiring 203p-1 functions as a dummy wiring and is provided to lower the resistance value of the wiring 302p-1 and improve connection strength.

It is possible to lower the resistance value of the wiring 302p connected to the wiring 202p and to improve connection strength by forming the wiring 202p as a dummy wiring as illustrated in FIG. 26. Additionally, according to Embodiment 2-7, it is also possible to curb influences of an increase in capacity caused between adjacent wirings and of variations in capacity similarly to Embodiment 2-1. It is also possible to obtain such an effect even when the pixels are miniaturized.

### Embodiment 3

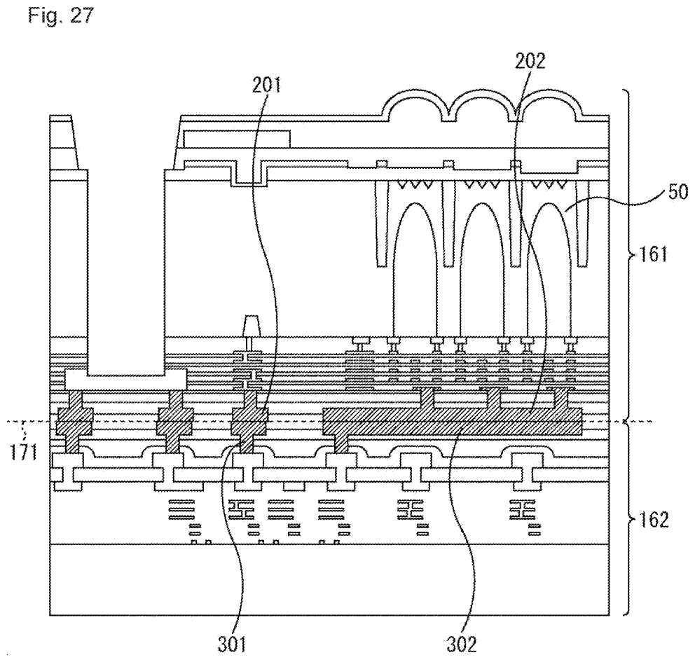

FIG. 27 is a diagram illustrating an example of a schematic sectional view of an imaging device according to Embodiment 3 of the present technique.

The imaging device according to Embodiment 3 has a configuration as a combination of Embodiment 1 and Embodiment 2. Although description will be given while description overlapping the description of Embodiment 1 and the description of Embodiment 2 will be appropriately omitted, it is possible to apply what has been described in Embodiment 1 and Embodiment 2 to Embodiment 3 as well.

The imaging device according to Embodiment 3 is configured to include a wiring 202 formed into a straight line shape and a wiring 302 formed into a straight line shape as illustrated in FIG. 27. Also, the wiring 202 and the wiring 302 are configured to be bonded in a plane in a lengthwise direction. In other words, in Embodiment 3, the area where the wiring 202 and the wiring 302 are bonded is larger than those in Embodiment 1 and Embodiment 2.

The wiring 202 is formed into a straight line shape on the side of the first semiconductor substrate 161 and is connected to the transfer transistor gates TRG1 or the transfer transistor gates TRG2 of the plurality of pixels 50 as illustrated in FIG. 27. The wiring 202 is connected to the wiring 302 formed in the second semiconductor substrate 162.

The wiring 302 is formed into a straight line shape as illustrated in FIG. 27. The wiring 302 includes one via-shaped connection terminal and is connected to a circuit in the second semiconductor substrate 162. Also, the wiring 302 is configured to be connected to the transfer transistor gates TRG1 or the transfer transistor gates TRG2 of the plurality of pixels 50 via the wiring 202.

### Embodiment 3-1

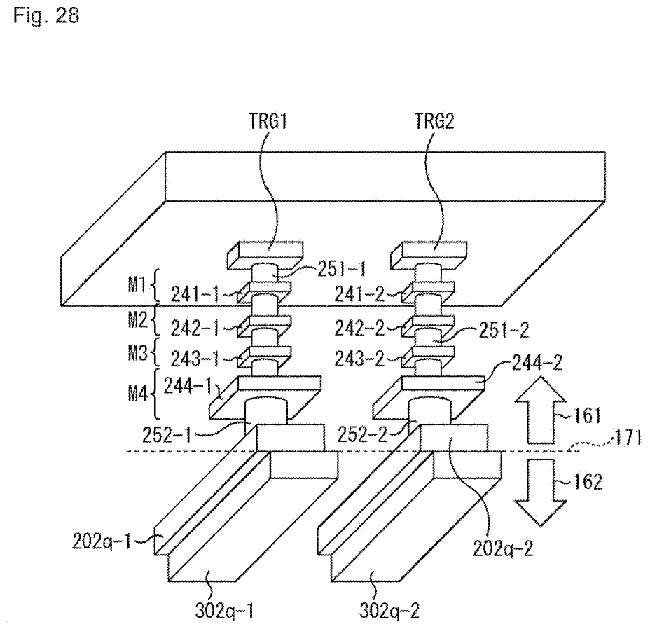

FIG. 28 is a diagram illustrating configurations of a wiring 202q and a wiring 302q according to Embodiment 3-1. An imaging device according to Embodiment 3-1 is configured to include a wiring 202q corresponding to the wiring 202a according to Embodiment 1-1 described above with reference to FIG. 12 and a wiring 302q corresponding to the wiring 302h according to Embodiment 2-1 described above with reference to FIG. 20.

The wiring 202q is formed into a rectangular parallelepiped shape, and transfer transistor gates TRG of the plurality of pixels 50 are connected thereto. The wiring 302q is formed into a rectangular parallelepiped shape and is connected to the wiring 202q.

Although FIG. 28 illustrates an example in which the wiring 202q and the wiring 302q are bonded with deviation, the illustration is for indicating that the large overlapping area prevents a connection failure from occurring even if deviation occurs in the bonding process, and the description does not indicate that they are bonded with deviation. In a case where the bonding surfaces between the wiring 202q and the wiring 302q have substantially the same shapes and substantially the size sizes, the entire bonding surface of the wiring 202q and the entire bonding surface of the wiring 302q can be bonded.

The wiring 202q and the wiring 302q are used as wirings for transmitting and receiving signals and are not dummy wirings. For example, the wiring 302f according to Embodiment 1-6 illustrated in FIG. 17 is formed into a rectangular parallelepiped shape and is configured to be connected to the wiring 202f, and in terms of the configuration, the wiring 302f has a configuration that is similar to that of the wiring 202q according to Embodiment 3-1 illustrated in FIG. 28. Also, the wiring 202n according to Embodiment 2-6 illustrated in FIG. 25, for example, is formed into a rectangular parallelepiped shape and is configured to be connected to the wiring 302n, and in terms of the configuration, the wiring 202n has a configuration that is similar to that of the wiring 202q according to Embodiment 3-1 illustrated in FIG. 28.

The wiring 302f according to Embodiment 1-6 illustrated in FIG. 17 and the wiring 202n according to Embodiment 2-6 illustrated in FIG. 25 are provided as dummy wirings while the wiring 202q and the wiring 302q according to Embodiment 3-1 illustrated in FIG. 28 are not dummy wirings, which is the difference therebetween.

According to the present technique, it is possible to curb occurrence of a connection failure even if accuracy of positioning when the second semiconductor substrate 162 and the first semiconductor substrate 161 are laminated (connected) is not high. Also, it is possible to employ a structure that curbs an increase in resistance value and to realize a low resistance. It is also possible to obtain such an effect even when the pixels are miniaturized.

### Embodiment 3-2

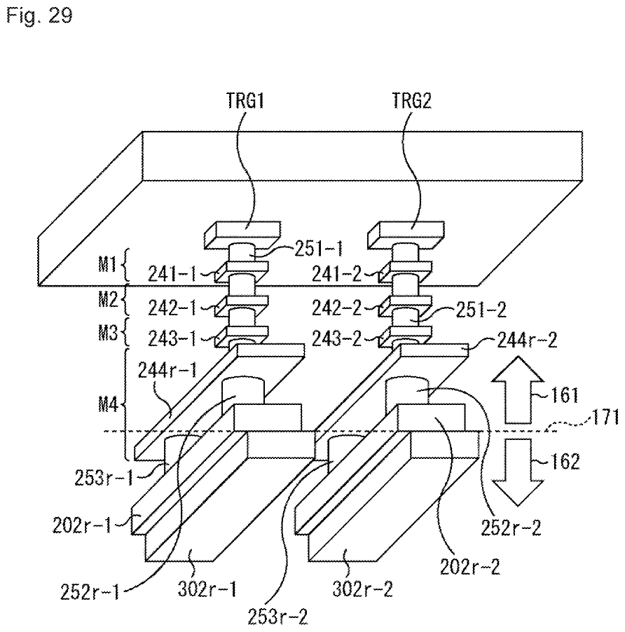

FIG. 29 is a diagram illustrating configurations of a wiring 202r and a wiring 302r according to Embodiment 3-2. An imaging device according to Embodiment 3-2 is configured to include a wiring 202r corresponding to the wiring 202b according to Embodiment 1-2 described above with reference to FIG. 13 and include a wiring 302r corresponding to the wiring 302h according to Embodiment 2-1 described above with reference to FIG. 20.

Also, the wiring 202r according to Embodiment 3-2 illustrated in FIG. 29 has a configuration in which a backing via 253r-1 is added to the configuration illustrated in FIG. 28 and the wiring 244r-1 is formed to have such a size with which the wiring 244r-1 can be connected to both the connection terminal 252r-1 and the backing via 253r-1.

Each of the wiring 202r and the wiring 302r is formed into a rectangular parallelepiped shape and is bonded to each other similarly to Embodiment 3-1 in FIG. 28.

According to the present technique, it is possible to curb occurrence of a connection failure even if accuracy of positioning when the second semiconductor substrate 162 and the first semiconductor substrate 161 are laminated (connected) is not high. Also, it is possible to employ a structure that curbs an increase in resistance value and to realize a low resistance. It is also possible to obtain such an effect even when the pixels are miniaturized.

### Embodiment 3-3

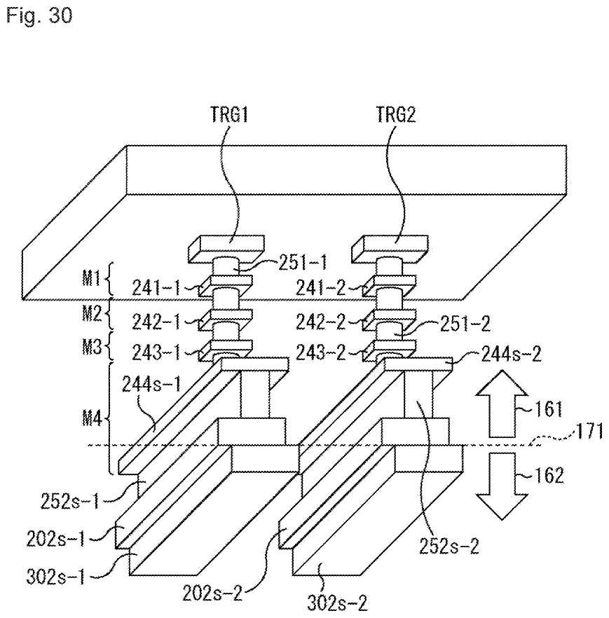

FIG. 30 is a diagram illustrating configurations of a wiring 202s and a wiring 302s according to Embodiment 3-3. The imaging device according to Embodiment 3-3 is configured to include a wiring 202s corresponding to the wiring 202c in Embodiment 1-3 described above with reference to FIG. 14 and include a wiring 302s corresponding to the wiring 302h according to Embodiment 2-1 described above with reference to FIG. 20.

The wiring 202s according to Embodiment 3-3 has a configuration that is similar to that of the wiring 202c according to Embodiment 1-3 illustrated in FIG. 14. The wiring 202s includes a connection terminal 252s formed into a rectangular parallelepiped shape, and the connection terminal 252s is provided between a wiring 202s and a wiring 244s.

Each of the wiring 202s and the wiring 302s is formed into a rectangular parallelepiped shape and is bonded to each other similarly to Embodiment 3-1 in FIG. 28.

According to the present technique, it is possible to curb occurrence of a connection failure even if accuracy of positioning when the second semiconductor substrate 162 and the first semiconductor substrate 161 are laminated (connected) is not high. Also, it is possible to employ a structure that curbs an increase in resistance value and to realize a low resistance. It is also possible to obtain such an effect even when the pixels are miniaturized.

### Embodiment 3-4

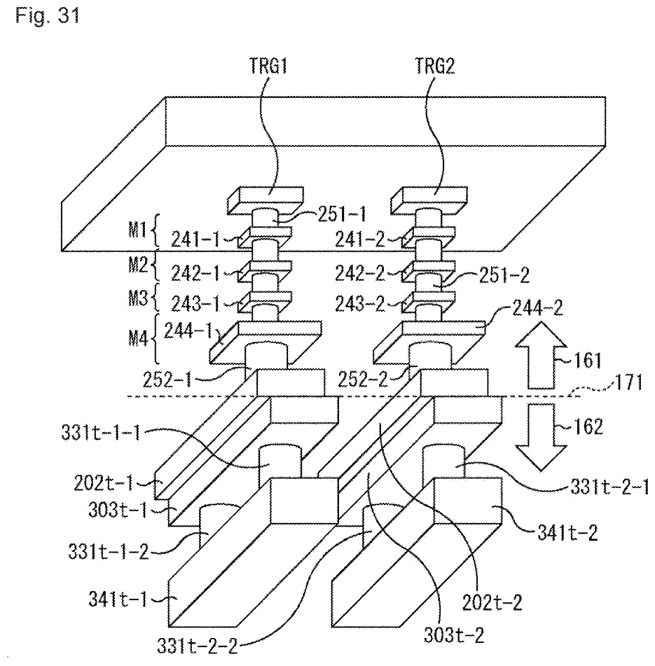

FIG. 31 is a diagram illustrating configurations of a wiring 202t and a wiring 302t according to Embodiment 3-4. An imaging device according to Embodiment 3-4 is configured to include a wiring 202t corresponding to the wiring 202a according to Embodiment 1-1 described above with reference to FIG. 12 and includes a wiring 302t corresponding to the wiring 302k according to Embodiment 2-4 described above with reference to FIG. 23.

The wiring 302t is connected to a backing via 331t-1-1 and a backing via 331t-1-2 formed in the second semiconductor substrate 162. The backing via 331t-1-1 and the backing via 331t-1-2 are connected to a wiring 341t-1.

Each of the wiring 202t and the wiring 302t is formed into a rectangular parallelepiped shape and is bonded to each other similarly to Embodiment 3-1 in FIG. 28.

According to the present technique, it is possible to curb occurrence of a connection failure even if accuracy of positioning when the second semiconductor substrate 162 and the first semiconductor substrate 161 are laminated (connected) is not high. Also, it is possible to employ a structure that curbs an increase in resistance value and to realize a low resistance. It is also possible to obtain such an effect even when the pixels are miniaturized.

### Embodiment 3-5

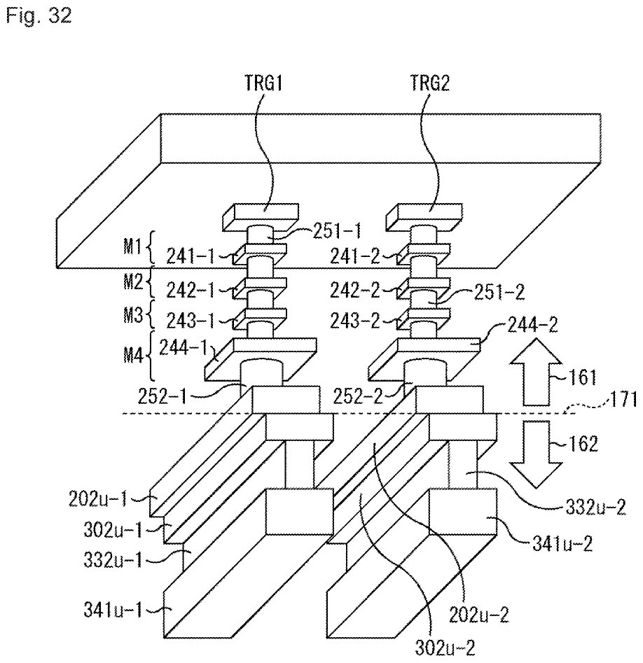

FIG. 32 is a diagram illustrating configurations of a wiring 202u and a wiring 302u according to Embodiment 3-5. An imaging device according to Embodiment 3-5 is configured to include a wiring 202u corresponding to the wiring 202a according to Embodiment 1-1 described above with reference to FIG. 12 and a wiring 302u corresponding to the wiring 302m according to Embodiment 2-5 described above with reference to FIG. 24.

The wiring 302u is connected to a backing trench 332u formed in the second semiconductor substrate 162. The backing trench 332u is connected to the wiring 341u. Each of the wiring 202u and the wiring 302u is formed into a rectangular parallelepiped shape and is bonded to each other similarly to Embodiment 3-1 in FIG. 28.

According to the present technique, it is possible to curb occurrence of a connection failure even if accuracy of positioning when the second semiconductor substrate 162 and the first semiconductor substrate 161 are laminated (connected) is not high. Also, it is possible to employ a structure that curbs an increase in resistance value and to realize a low resistance. It is also possible to obtain such an effect even when the pixels are miniaturized.

Embodiment 3 may be a combination other than the aforementioned combination of Embodiment 1 and Embodiment 2.

### <Configuration Example of Distance Measurement Module>

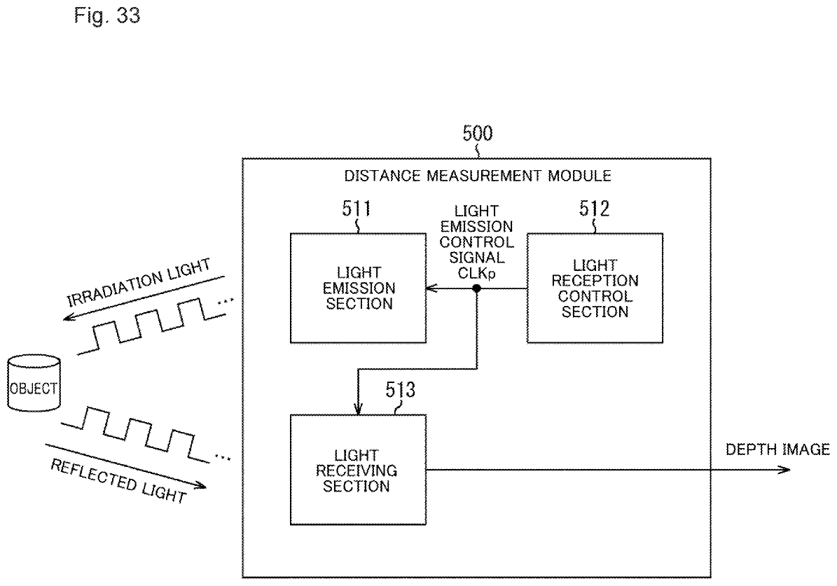

The distance measurement device 10 according to the above embodiments may be formed as a distance measurement module. FIG. 33 is a block diagram illustrating a configuration example of a distance measurement module using the aforementioned imaging device (for example, the imaging device including the pixels 50 explained with reference to FIG. 8 and the like).

A distance measurement module 500 includes a light emission section 511, a light emission control section 512, and a light receiving section 513. The light emission section 511 includes a light source that emits light having a predetermined wavelength, emits irradiation light with a periodically varying brightness, and irradiates an object therewith. For example, the light emission section 511 has, as the light source, a light emitting diode that emits infrared light with a wavelength within a range of 780 nm to 1000 nm and generates the irradiation light in synchronization with a light emission control signal CLKp with a rectangular wave supplied from the light emission control section 512.

Note that the light emission control signal CLKp is not limited to a rectangular wave as long as it is a periodic signal. For example, the light emission control signal CLKp may be a sine wave.

The light emission control section 512 supplies the light emission control signal CLKp to the light emission section 511 and the light receiving section 513 and controls an irradiation timing of irradiation light. The frequency of the light emission control signal CLKp is, for example, 20 megahertz (MHz). Note that the frequency of the light emission control signal CLKp is not limited to 20 megahertz (MHz) and may be 5 megahertz (MHz) or the like.

The light receiving section 513 receives reflected light reflected from an object, calculates distance information for each pixel in accordance with a result of light reception, and generates and outputs a depth image in which a depth value corresponding to a distance to the object (subject) is stored as a pixel value.

An imaging device having the pixel structure of any of the aforementioned embodiments is used as the light receiving section 513. For example, the imaging device as the light receiving section 513 calculates distance information for each pixel from signal intensity in accordance with a charge distributed to the floating diffusion regions FD1 or FD2 of each pixel in the pixel array section 41 on the basis of the light emission control signal CLKp. Note that the number of taps of the pixel may be four taps or the like as described above.

As described above, it is possible to incorporate the imaging device having the aforementioned pixel structure as the light receiving section 513 of the distance measurement module 500 that obtains information regarding the distance to the object by the indirect ToF scheme and outputs the distance information. It is thus possible to improve distance measurement properties of the distance measurement module 500.

### <Configuration Example of Electronic Equipment>

The imaging device can be applied to a distance measurement module as described above, and can also be applied to various kinds of electronic equipment such as, for example, imaging devices such as digital still cameras and digital video cameras equipped with a distance measurement function and smartphones equipped with a distance measurement function.

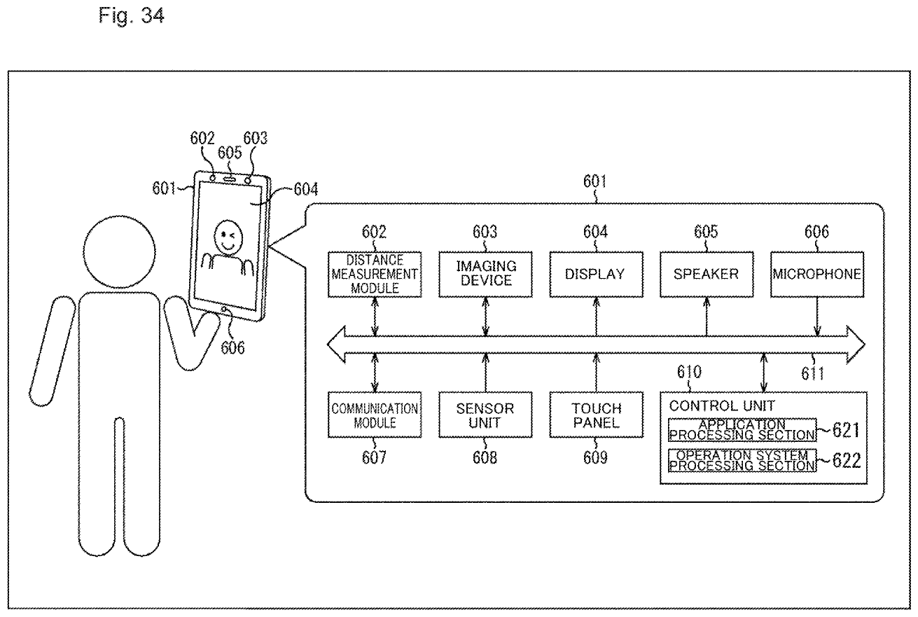

FIG. 34 is a block diagram illustrating a configuration example of a smartphone as electronic equipment to which the present technique is applied.

As illustrated in FIG. 34, a smartphone 601 is configured such that a distance measurement module 602, an imaging device 603, a display 604, a speaker 605, a microphone 606, a communication module 607, a sensor unit 608, a touch panel 609, and a control unit 610 are connected to each other via a bus 611. Further, the control unit 610 has functions as an application processing section 621 and an operation system processing section 622 by a CPU executing a program.

The distance measurement module 500 illustrated in FIG. 33 is applied to the distance measurement module 602. For example, the distance measurement module 602 is disposed on the front surface of the smartphone 601, and can output a depth value of a surface shape of the face, hand, finger, or the like of a user of the smartphone 601 as a distance measurement result by performing distance measurement on a user of the smartphone 601.

The imaging device 603 is disposed on the front surface of the smartphone 601, and acquires an image capturing the user of the smartphone 601 by imaging the user as a subject. Note that although not illustrated in the drawing, a configuration in which the imaging device 603 is also disposed on the back surface of the smartphone 601 may be adopted.

The display 604 displays an operation screen for performing processing by the application processing section 621 and the operation system processing section 622, an image captured by the imaging device 603, and the like. The speaker 605 and the microphone 606 perform, for example, outputting of sound from a counterpart and collecting of user's sound at the time of a call using the smartphone 601.

The communication module 607 performs network communication through a communication network such as the Internet, a public telephone network, a wide area communication network for wireless mobiles such as a so-called 4G line and 5G line, a wide area network (WAN), and a local area network (LAN), short-range wireless communication such as Bluetooth (registered trademark) and near field communication (NFC), and the like. The sensor unit 608 senses a speed, acceleration, proximity, and the like, and the touch panel 609 acquires a user's touch operation on the operation screen displayed on the display 604.

The application processing section 621 performs processing for providing various services through the smartphone 601. For example, the application processing section 621 can perform processing of creating a face by computer graphics that virtually reproduces the user's facial expression on the basis of a depth value supplied from the distance measurement module 602 and displaying the created face on the display 604. In addition, the application processing section 621 can perform processing of creating, for example, three-dimensional shape data of an arbitrary three-dimensional object on the basis of a depth value supplied from the distance measurement module 602.

The operation system processing section 622 performs processing for realizing basic functions and operations of the smartphone 601. For example, the operation system processing section 622 can perform processing for authenticating a user's face on the basis of a depth value supplied from the distance measurement module 602, and unlocking the smartphone 601. In addition, the operation system processing section 622 can perform, for example, processing for recognizing a user's gesture on the basis of a depth value supplied from the distance measurement module 602, and can perform processing for inputting various operations according to the gesture.

In the smartphone 601 configured in this manner, the aforementioned distance measurement module 500 is applied as the distance measurement module 602, and it is thus possible to perform, for example, processing for measuring and displaying a distance to a predetermined object or creating and displaying three-dimensional shape data of the predetermined object, and the like.

### <Application to Mobile Object>

The technique of the present disclosure (the present technique) can be applied to various products. For example, the technique according to the present disclosure may be realized as a device mounted on any type of mobile object such as an automobile, an electric automobile, a hybrid electric automobile, a motorcycle, a bicycle, a personal mobility device, an airplane, a drone, a ship, a robot, or the like.

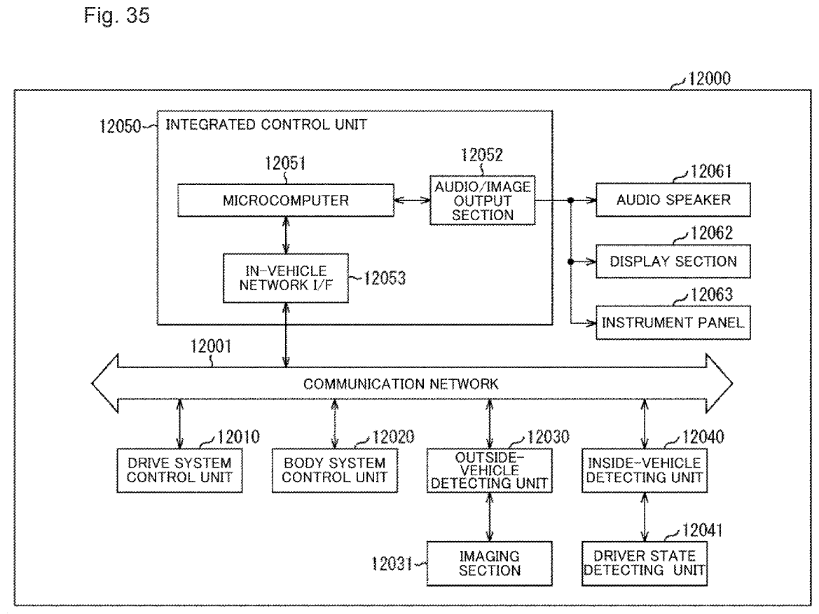

FIG. 35 is a block diagram illustrating a schematic configuration example of a vehicle control system, which is an example of a mobile object control system to which the technique according to the present disclosure can be applied.

The vehicle control system 12000 includes a plurality of electronic control units connected via a communication network 12001. In the example illustrated in FIG. 35, the vehicle control system 12000 includes a drive system control unit 12010, a body system control unit 12020, an outside-vehicle information detecting unit 12030, an inside-vehicle information detecting unit 12040, and an integrated control unit 12050. Also, a microcomputer 12051, an audio/image output section 12052, and an in-vehicle network interface (I/F) 12053 are illustrated as functional configurations of the integrated control unit 12050.

The drive system control unit 12010 controls an operation of an apparatus related to a drive system of a vehicle according to various programs. For example, the drive system control unit 12010 functions as a driving force generator for generating a driving force of a vehicle such as an internal combustion engine or a driving motor, a driving force transmission mechanism for transmitting a driving force to wheels, a steering mechanism for adjusting a turning angle of a vehicle, and a control apparatus such as a braking apparatus that generates a braking force of a vehicle.

The body system control unit 12020 controls operations of various devices mounted in the vehicle body according to various programs. For example, the body system control unit 12020 functions as a control device of a keyless entry system, a smart key system, a power window device, or various lamps such as a headlamp, a back lamp, a brake lamp, a turn signal, and a fog lamp. In this case, radio waves transmitted from a portable device that substitutes for a key or signals of various switches may be input to the body system control unit 12020. The body system control unit 12020 receives inputs of the radio waves or signals and controls a door lock device, a power window device, and a lamp of the vehicle.

The outside-vehicle information detecting unit 12030 detects information on the outside of the vehicle having the vehicle control system 12000 mounted thereon. For example, an imaging section 12031 is connected to the outside-vehicle information detecting unit 12030. The outside-vehicle information detecting unit 12030 causes the imaging section 12031 to capture an image of the outside of the vehicle and receives the captured image. The outside-vehicle information detecting unit 12030 may perform object detection processing or distance detection processing for people, cars, obstacles, signs, and letters on the road on the basis of the received image.

The imaging section 12031 is an optical sensor that receives light and outputs an electrical signal according to the amount of the received light. The imaging section 12031 can also output the electrical signal as an image or distance measurement information. In addition, the light received by the imaging section 12031 may be visible light or invisible light such as infrared light.

The inside-vehicle information detecting unit 12040 detects information on the inside of the vehicle. For example, a driver state detecting section 12041 that detects a driver's state is connected to the inside-vehicle information detecting unit 12040. The driver state detecting section 12041 includes, for example, a camera that captures an image of a driver, and the inside-vehicle information detecting unit 12040 may calculate a degree of fatigue or concentration of the driver or may determine whether or not the driver is dozing on the basis of detection information input from the driver state detecting section 12041.

The microcomputer 12051 can computer a control target value of a drive force generation device, a steering mechanism, or a brake device on the basis of inside-vehicle and outside-vehicle information acquired by the outside-vehicle information detecting unit 12030 or the inside-vehicle information detecting unit 12040 and output a control command to the drive system control unit 12010. For example, the microcomputer 12051 can perform cooperative control for the purpose of realizing functions of an advanced drive assistance system (ADAS) including collision avoidance or impact mitigation of the vehicle, following traveling based on the inter-vehicle distance, vehicle speed maintaining traveling, a collision warming of the vehicle, a lane deviation warning of the vehicle, and the like.

Further, the microcomputer 12051 can perform cooperative control for the purpose of automated driving or the like in which autonomous travel is performed without depending on operations of the driver, by controlling the driving force generator, the steering mechanism, or the braking device and the like on the basis of information about the surroundings of the vehicle, the information being acquired by the outside-vehicle information detecting unit 12030 or the inside-vehicle information detecting unit 12040.

In addition, the microcomputer 12051 can output a control command to the body system control unit 12030 based on the information outside the vehicle acquired by the outside-vehicle information detecting unit 12030. For example, the microcomputer 12051 can perform coordinated control for the purpose of antiglare such as switching a high beam to a low beam by controlling a headlamp according to a position of a preceding vehicle or an oncoming vehicle detected by the outside-vehicle information detecting unit 12030.

The audio/image output section 12052 transmits an output signal of at least one of sound and an image to an output device capable of visually or audibly notifying a passenger or the outside of the vehicle of information. In the example of FIG. 35, an audio speaker 12061, a display section 12062, and an instrument panel 12063 are illustrated as examples of the output device. The display section 12062 may include at least one of an on-board display and a head-up display, for example.

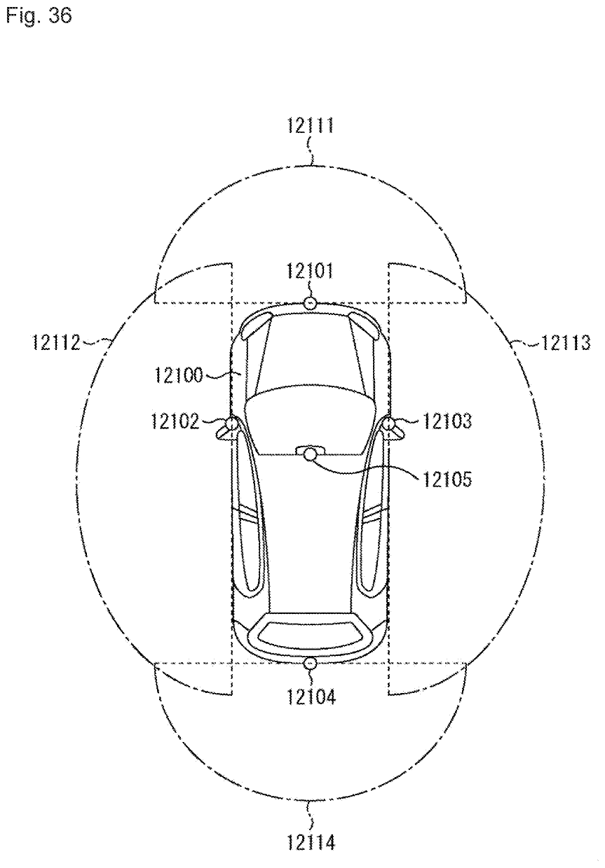

FIG. 36 is a diagram illustrating an example of an installation position of the imaging section 12031.

In FIG. 36, the imaging section 12031 includes imaging sections 12101, 12102, 12103, 12104, and 12105.

The imaging sections 12101, 12102, 12103, 12104, and 12105 are provided at, for example, positions of a front nose, side mirrors, a rear bumper, a back door, an upper portion of a vehicle internal front windshield, and the like of the vehicle 12100. The imaging section 12101 provided on a front nose and the imaging section 12105 provided in an upper portion of the vehicle internal front windshield mainly acquire images in front of the vehicle 12100. The imaging sections 12102 and 12103 provided in the side mirrors mainly acquire images on the lateral sides of the vehicle 12100. The imaging section 12104 included in the rear bumper or the back door mainly acquires an image of an area behind the vehicle 12100. The imaging section 12105 included in the upper portion of the windshield inside the vehicle is mainly used for detection of a preceding vehicle, a pedestrian, an obstacle, a traffic signal, a traffic sign, a lane, or the like.

FIG. 36 illustrates an example of imaging ranges of the imaging sections 12101 to 12104. An imaging range 12111 indicates an imaging range of the imaging section 12101 provided at the front nose, imaging ranges 12112 and 12113 respectively indicate the imaging ranges of the imaging sections 12102 and 12103 provided at the side-view mirrors, and an imaging range 12114 indicates the imaging range of the imaging section 12104 provided at the rear bumper or the back door. For example, by superimposing image data captured by the imaging sections 12101 to 12104, it is possible to obtain a bird's-eye view image viewed from the upper side of the vehicle 12100.

At least one of the imaging sections 12101 to 12104 may have a function for obtaining distance information. For example, at least one of the imaging sections 12101 to 12104 may be a stereo camera constituted by a plurality of imaging elements or may be an imaging element that has pixels for phase difference detection.

For example, the microcomputer 12051 can extract, as a vehicle ahead, a closest three-dimensional object that is on a traveling path of the vehicle 12100, in particular, and travels at a predetermined speed (not less than 0 km/h, for example) in substantially the same direction as that of the vehicle 12100 by obtaining the distance to each three-dimensional object in the imaging ranges 12111 to 12114 and a temporal change in the distance (relative speeds with respect to the vehicle 12100) on the basis of the distance information obtained from the imaging sections 12101 to 12104. Moreover, the microcomputer 12051 can set an in-vehicle distance to be secured from the vehicle ahead in advance and perform automated brake control (including following stop control), automated acceleration control (including following start control), and the like. Thus, it is possible to perform cooperative control for the purpose of, for example, automated driving in which the vehicle travels in an automated manner without requiring a driver to perform operations.

For example, the microcomputer 12051 can classify and extract three-dimensional data regarding three-dimensional objects into two-wheeled vehicles, normal vehicles, large vehicles, pedestrians, and other three-dimensional objects such as electric poles based on distance information obtained from the imaging sections 12101 to 12104 and can use the three-dimensional data to perform automated avoidance of obstacles. For example, the microcomputer 12051 differentiates surrounding obstacles of the vehicle 12100 into obstacles which can be viewed by the driver of the vehicle 12100 and obstacles which are difficult to view. Then, the microcomputer 12051 determines a collision risk indicating the degree of risk of collision with each obstacle, and when the collision risk is equal to or higher than a set value and there is a possibility of collision, an alarm is output to the driver through the audio speaker 12061 or the display section 12062, forced deceleration or avoidance steering is performed through the drive system control unit 12010, and thus it is possible to perform driving support for collision avoidance.

At least one of the imaging sections 12101 to 12104 may be an infrared camera that detects infrared rays. For example, the microcomputer 12051 can recognize a pedestrian by determining whether there is a pedestrian in the captured image of the imaging sections 12101 to 12104. Such pedestrian recognition is performed by, for example, a procedure in which feature points in the captured images of the imaging sections 12101 to 12104 as infrared cameras are extracted and a procedure in which pattern matching processing is performed on a series of feature points indicating an outline of an object to determine whether or not the object is a pedestrian. When the microcomputer 12051 determines that there is a pedestrian in the captured images of the imaging sections 12101 to 12104 and the pedestrian is recognized, the audio/image output section 12052 controls the display section 12062 so that a square contour line for emphasis is superimposed and displayed with the recognized pedestrian. In addition, the audio/image output section 12052 may control the display section 12062 so that an icon indicating a pedestrian or the like is displayed at a desired position.

The system as used herein refers to an entire device configured by a plurality of devices.

The effects described in the present specification are merely examples and are not limited, and other effects may be obtained.

Embodiments of the present technique are not limited to the above-described embodiment and various modifications can be made within the scope of the present technique without departing from the gist of the present technique.

The present technique can also be configured as follows.

(1)

An imaging element including: a semiconductor layer in which pixels including photodiodes, first transfer transistors that transfer a charge generated by the photodiodes to a first charge accumulation section, and second transfer transistors that transfer the charge generated by the photodiodes to a second charge accumulation section are arranged in a matrix shape; and on a side of a second surface of the wiring layer that is opposite to a first surface on which the semiconductor layer is laminated, a first wiring to which the first transfer transistors of the plurality of pixels arranged in a row direction or a column direction from among the pixels arranged in the matrix shape are connected and a second wiring to which the second transfer transistors of the plurality of pixels are connected being included.

(2)

The imaging element according to (1) above, in which each of the first wiring and the second wiring is a conductor formed into a rectangular parallelepiped shape.

(3)

The imaging element according to (1) or (2) above, in which each of the first wiring and the second wiring is connected to a wiring formed into a rectangular parallelepiped shape in the wiring layer via two or more vias per pixel.

(4)

The imaging element according to (1) or (2) above, in which each of the first wiring and the second wiring is connected to a wiring formed into a rectangular parallelepiped shape in the wiring layer via a trench formed into a rectangular parallelepiped shape.

(5)

The imaging element according to (1) or (2) above, in which each of the first wiring and the second wiring is connected to two or more vias formed in a semiconductor substrate laminated on the second surface and is connected to a wiring formed into a rectangular parallelepiped shape in the semiconductor substrate via the vias.

(6)

The imaging element according to (1) or (2) above, in which each of the first wiring and the second wiring is connected to a trench formed into a rectangular parallelepiped shape formed in a semiconductor substrate laminated on the second surface and is connected to a wiring formed into a rectangular parallelepiped shape in the semiconductor substrate via the trench.

(7)

The imaging element according to (1) or (2) above, in which each of the first wiring and the second wiring is connected to a wiring formed into a rectangular parallelepiped shape formed on a semiconductor substrate laminated on the second surface.

(8)

The imaging element according to (1) above, in which each of the first wiring and the second wiring is connected to two or more wirings per pixel that are formed into rectangular parallelepiped shapes formed on a semiconductor substrate laminated on the second surface.

(9)

An imaging device including: a semiconductor layer in which pixels including photodiodes, first transfer transistors that transfer a charge generated by the photodiodes to a first charge accumulation section, and second transfer transistors that transfer the charge generated by the photodiodes to a second charge accumulation section are arranged in a matrix shape; and a wiring layer that is laminated on the semiconductor layer, a first wiring to which the first transfer transistors are connected and a second wiring to which the second transfer transistors are connected being included on a side of a second surface of the wiring layer that is opposite to a first surface on which the semiconductor layer is laminated, and a third wiring to which the first wiring of the plurality of pixels arranged in a row direction or a column direction from among the pixels arranged in the matrix shape is connected and a fourth wiring to which the second transfer transistors of the plurality of pixels are connected being included on a side of a surface of a semiconductor substrate, which is laminated on a side of the second surface, and in contact with the second surface.

(10)

The imaging device according to (9) above, in which the semiconductor substrate is a substrate on which a circuit that processes signals from the pixels is formed.

(11)

The imaging device according to (9) or (10) above, in which each of the third wiring and the fourth wiring is a conductor formed into a rectangular parallelepiped shape.

(12)

The imaging device according to any of (9) to (11) above, in which each of the third wiring and the fourth wiring is connected to a wiring formed into a rectangular parallelepiped shape in the wiring layer via two or more vias per pixel.

(13)

The imaging device according to any of (9) to (11) above, in which each of the third wiring and the fourth wiring is connected to a wiring formed into a rectangular parallelepiped shape in the wiring layer via a trench formed into a rectangular parallelepiped shape.

(14)

The imaging device according to any of (9) to (11) above, in which each of the third wiring and the fourth wiring is connected to two or more vias formed in the semiconductor substrate and is connected to a wiring formed into a rectangular parallelepiped shape in the semiconductor substrate via the vias.

(15)

The imaging device according to any of (9) to (11) above, in which each of the third wiring and the fourth wiring is connected to a trench formed into a rectangular parallelepiped shape formed in the semiconductor substrate and is connected to a wiring formed into a rectangular parallelepiped shape in the semiconductor substrate via the trench.

(16)

The imaging device according to any of (9) to (11) above, in which each of the third wiring and the fourth wiring is connected to a wiring formed into a rectangular parallelepiped shape formed in the wiring layer.

(17)

The imaging device according to any of (9) to (11) above, in which each of the third wiring and the fourth wiring is connected to two or more wirings per pixel that are formed into rectangular parallelepiped shapes formed in the wiring layer.

(18)

Electronic equipment including: a distance measurement module that includes an imaging element including a semiconductor layer and a wiring layer, pixels including photodiodes, first transfer transistors that transfer a charge generated by the photodiodes to a first charge accumulation section, and second transfer transistors that transfer the charge generated by the photodiodes to a second charge accumulation section being arranged in a matrix shape in the semiconductor layer, the wiring layer being laminated on the semiconductor layer, a first wiring to which the first transfer transistors of the plurality of pixels arranged in a row direction or a column direction from among the pixels arranged in the matrix shape are connected and a second wiring to which the second transfer transistors of the plurality of pixels are connected being included on a side of a second surface of the wiring layer that is opposite to a first surface on which the semiconductor layer is laminated, a light source that emits irradiation light with a periodically varying brightness, and a light emission control section that controls an irradiation timing of the irradiation light.

(19)

Electronic equipment including: a distance measurement module that includes an imaging device including a semiconductor layer and a wiring layer, pixels including photodiodes, first transfer transistors that transfer a charge generated by the photodiodes to a first charge accumulation section, and second transfer transistors that transfer the charge generated by the photodiodes to a second charge accumulation section being arranged in a matrix shape in the semiconductor layer, the wiring layer being laminated on the semiconductor layer, a first wiring to which the first transfer transistors are connected and a second wiring to which the second transfer transistors are connected being included on a side of a second surface of the wiring layer that is opposite to a first surface on which the semiconductor layer is laminated, and a third wiring to which the first wiring of the plurality of pixels arranged in a row direction or a column direction from among the pixels arranged in the matrix shape is connected and a fourth wiring to which the second transfer transistors of the plurality of pixels are connected being included on a side of a surface of a semiconductor substrate, which is laminated on the side of the second surface, and in contact with the second surface, a light source that emits irradiation light with a periodically varying brightness, and a light emission control section that controls an irradiation timing of the irradiation light.

### REFERENCE SIGNS LIST

10 Distance measurement device
11 Lens
12 Light receiving section
13 Signal processing section
14 Light emission section
15 Light emission control section
21 Pattern switching section
22 Distance image generation section
41 Pixel array section
42 Vertical driving section
43 Column processing section
44 Horizontal driving section
45 System control section
46 Pixel driving line
47 Vertical signal line
48 Signal processing section
50 Pixel
51 Tap
52 Transfer transistor
54 Reset transistor
56 Discharge transistor
57 Amplification transistor
58 Selection transistor
60 Additional capacitance section
61 Photodiode
65 Well contact
111 Semiconductor substrate
112 Multilayered wiring layer
113 Anti-reflection film
114 Pixel boundary section
115 Inter-pixel light shielding film
116 Flattened film
117 On-chip lens
121 Semiconductor region
122 Semiconductor region
123 Hafnium oxide film
124 Aluminum oxide film
125 Silicon oxide film
131 Inter-pixel separation section
132 Interlayer insulating film
133 Wiring
134 Wiring
151 Anti-reflection film
153 PD upper region
161 First semiconductor substrate
162 Second semiconductor substrate
163 Pixel region
164 Control circuit
165 Logic circuit
166 Analog circuit
171 Bonding surface
201, 202, 203, 241, 242, 243, 244 Wiring
251 Via
252 Connection terminal
253 Backing via
301, 302 Wiring
331 Backing via
332 Backing trench
341 Wiring

What is claimed is:

1. An imaging element, comprising:
a semiconductor layer in which pixels including photodiodes, first transfer transistors that transfer a charge generated by the photodiodes to a first charge accumulation section, and second transfer transistors that transfer the charge generated by the photodiodes to a second charge accumulation section are arranged in a matrix shape; and
a wiring layer that is laminated on the semiconductor layer,
wherein a first wiring to which the first transfer transistors of the plurality of pixels arranged in a row direction or a column direction from among the pixels arranged in the matrix shape are connected and a second wiring to which the second transfer transistors of the plurality of pixels are connected are included on a side of a second surface of the wiring layer that is opposite to a first surface on which the semiconductor layer is laminated.

2. The imaging element according to claim 1, wherein each of the first wiring and the second wiring is a conductor formed into a rectangular parallelepiped shape.

3. The imaging element according to claim 1, wherein each of the first wiring and the second wiring is connected to a wiring formed into a rectangular parallelepiped shape in the wiring layer via two or more vias per pixel.

4. The imaging element according to claim 1, wherein each of the first wiring and the second wiring is connected to a wiring formed into a rectangular parallelepiped shape in the wiring layer via a trench formed into a rectangular parallelepiped shape.

5. The imaging element according to claim 1, wherein each of the first wiring and the second wiring is connected to two or more vias formed in a semiconductor substrate laminated on the second surface and is connected to a wiring formed into a rectangular parallelepiped shape in the semiconductor substrate via the vias.

6. The imaging element according to claim 1, wherein each of the first wiring and the second wiring is connected to a trench formed into a rectangular parallelepiped shape formed in a semiconductor substrate laminated on the second surface and is connected to a wiring formed into a rectangular parallelepiped shape in the semiconductor substrate via the trench.

7. The imaging element according to claim 1, wherein each of the first wiring and the second wiring is connected to a wiring formed into a rectangular parallelepiped shape formed on a semiconductor substrate laminated on the second surface.

8. The imaging element according to claim 1, wherein each of the first wiring and the second wiring is connected to two or more wirings per pixel that are formed into rectangular parallelepiped shapes formed on a semiconductor substrate laminated on the second surface.

9. An imaging device, comprising:
a semiconductor layer in which pixels including photodiodes, first transfer transistors that transfer a charge generated by the photodiodes to a first charge accumulation section, and second transfer transistors that transfer the charge generated by the photodiodes to a second charge accumulation section are arranged in a matrix shape; and
a wiring layer that is laminated on the semiconductor layer,
wherein a first wiring to which the first transfer transistors are connected and a second wiring to which the second transfer transistors are connected are included on a side of a second surface of the wiring layer that is opposite to a first surface on which the semiconductor layer is laminated, and
a third wiring to which the first wiring of the plurality of pixels arranged in a row direction or a column direction from among the pixels arranged in the matrix shape is connected and a fourth wiring to which the second transfer transistors of the plurality of pixels are connected are included on a side of a surface of a semiconductor substrate, which is laminated on a side of the second surface, and in contact with the second surface.

10. The imaging device according to claim 9, wherein the semiconductor substrate is a substrate on which a circuit that processes signals from the pixels is formed.

11. The imaging device according to claim 9, wherein each of the third wiring and the fourth wiring is a conductor formed into a rectangular parallelepiped shape.

12. The imaging device according to claim 9, wherein each of the third wiring and the fourth wiring is connected to a wiring formed into a rectangular parallelepiped shape in the wiring layer via two or more vias per pixel.

13. The imaging device according to claim 9, wherein each of the third wiring and the fourth wiring is connected to a wiring formed into a rectangular parallelepiped shape in the wiring layer via a trench formed into a rectangular parallelepiped shape.

14. The imaging device according to claim 9, wherein each of the third wiring and the fourth wiring is connected to two or more vias formed in the semiconductor substrate and is connected to a wiring formed into a rectangular parallelepiped shape in the semiconductor substrate via the vias.

15. The imaging device according to claim 9, wherein each of the third wiring and the fourth wiring is connected to a trench formed into a rectangular parallelepiped shape formed in the semiconductor substrate and is connected to a wiring formed into a rectangular parallelepiped shape in the semiconductor substrate via the trench.

16. The imaging device according to claim 9, wherein each of the third wiring and the fourth wiring is connected to a wiring formed into a rectangular parallelepiped shape formed in the wiring layer.

17. The imaging device according to claim 9, wherein each of the third wiring and the fourth wiring is connected to two or more wirings per pixel that are formed into rectangular parallelepiped shapes formed in the wiring layer.

18. Electronic equipment, comprising:
a distance measurement module that includes
an imaging element including a semiconductor layer and a wiring layer, pixels including photodiodes, first transfer transistors that transfer a charge generated by the photodiodes to a first charge accumulation section, and second transfer transistors that transfer the charge generated by the photodiodes to a second charge accumulation section being arranged in a matrix shape in the semiconductor layer, the wiring layer being laminated on the semiconductor layer, a first wiring to which the first transfer transistors of the plurality of pixels arranged in a row direction or a column direction from among the pixels arranged in the matrix shape are connected and a second wiring to which the second transfer transistors of the plurality of pixels are connected being included on a side of a second surface of the wiring layer that is opposite to a first surface on which the semiconductor layer is laminated,
a light source that emits irradiation light with a periodically varying brightness, and
a light emission control section that controls an irradiation timing of the irradiation light.

19. Electronic equipment comprising:
a distance measurement module that includes
an imaging device including a semiconductor layer and a wiring layer, pixels including photodiodes, first transfer transistors that transfer a charge generated by the photodiodes to a first charge accumulation section, and second transfer transistors that transfer the charge generated by the photodiodes to a second charge accumulation section being arranged in a matrix shape in the semiconductor layer, the wiring layer being laminated on the semiconductor layer, a first wiring to which the first transfer transistors are connected and a second wiring to which the second transfer transistors are connected being included on a side of a second surface of the wiring layer that is opposite to a first surface on which the semiconductor layer is laminated, and a third wiring to which the first wiring of the plurality of pixels arranged in a row direction or a column direction from among the pixels arranged in the matrix shape is connected and a fourth wiring to which the second transfer transistors of the plurality of pixels are connected being included on a side of a surface of a semiconductor substrate, which is laminated on the side of the second surface, and in contact with the second surface,
a light source that emits irradiation light with a periodically varying brightness, and
a light emission control section that controls an irradiation timing of the irradiation light.
